(19) United States
(12) Patent Application Publication
(10) Pub. No.: US 2024/0034930 A1
(43) Pub. Date: Feb. 1, 2024

(54) PATTERNING MATERIAL, PATTERNING COMPOSITION, AND PATTERN FORMING METHOD

(71) Applicant: HUAWEI TECHNOLOGIES CO., LTD., SHENZHEN (CN)

(72) Inventors: Lei ZHANG, Fuzhou (CN); Xiaofeng YI, Fuzhou (CN); Di WANG, Fuzhou (CN); Yu ZHANG, Shenzhen (CN)

(21) Appl. No.: 18/486,684

(22) Filed: Oct. 13, 2023

Related U.S. Application Data
(63) Continuation of application No. PCT/CN2022/086417, filed on Apr. 12, 2022.

(30) Foreign Application Priority Data
Apr. 14, 2021 (CN) 202110402526.2

(51) Int. Cl. C09K 11/62; C09K 11/02

(52) U.S. Cl. CPC C09K 11/626; C09K 11/02; C09K 2211/10

(57) ABSTRACT

This application relates to a patterning material, a patterning composition, and a pattern forming method. The patterning material in this application includes a metal-oxygen cluster framework, a radiation-sensitive organic ligand, and a second ligand. The radiation-sensitive organic ligand coordinates with a metal M through a coordination atom. The coordination atom is at least one of: an oxygen atom, a sulfur atom, a selenium atom, a nitrogen atom, or a phosphorus atom. The radiation-sensitive organic ligand is a monodentate ligand or a polydentate ligand with a denticity of two or more. The second ligand is an inorganic ion or a coordination group.

### CROSS-REFERENCE TO RELATED APPLICATIONS

This application is a continuation of International Application No. PCT/CN2022/086417, filed on Apr. 12, 2022, which claims priority to Chinese Patent Application No. 202110402526.2, filed on Apr. 14, 2021. The disclosures of the aforementioned applications are hereby incorporated by reference in their entirety.

### TECHNICAL FIELD

This application relates to the field of a patterning material, a radiation-sensitive patterning composition, a pattern forming method, a patterned substrate, a method for patterning a substrate, and an integrated circuit device, and in particular, to a patterning material, a radiation-sensitive patterning composition including the patterning material, a pattern forming method using the patterning material, a patterned substrate formed using the patterning material, a method for patterning a substrate performed using the patterned substrate, and an integrated circuit device including a surface structure formed by using the method for patterning the substrate.

### BACKGROUND

With the miniaturization and high performance of consumer electronic products, especially various terminals such as tablet computers, notebook computers, digital cameras, mobile phones, wearable electronic devices, and virtual reality devices, the requirements for high integration of integrated circuit (IC) devices are increasingly high, computing power of chips per unit area needs to be gradually improved, and efficiency of electronic products needs to be increasingly high. To support rapid development of the integrated circuit industry, especially for the improvement of the computing power of chips per unit area, that is, corresponding critical dimensions becoming smaller, rapid development of patterning technology is inevitable. A patterning process of integrated circuits has developed to support mass production of the chip process. In particular, the patterning process may include the following steps: A coated substrate film layer is irradiated through a template of a given pattern, to form an irradiated structure with an irradiated coating region and an unirradiated coating region. The irradiated structure or the unirradiated structure is selectively dissolved and washed. A pattern formed by the residual material is the same as the pattern on the template. The residual patterning material may be anti-etching in an etching step. In an embodiment, a bottom-layer protection material may be provided, so that the substrate is not etched or is slowly etched. Then, the pattern is formed and transferred to the bottom-layer substrate, to form the pattern on a wafer, for example, a silicon wafer. This pattern is the pattern obtained through initial selective exposure. A specific process is shown in FIG. 1.

In the most advanced process of patterning using a ray with a short wavelength of less than 15 nm, the patterning technology has low transmission efficiency of a light source and requires high sensitivity of a patterning material. In an embodiment, an exposure energy is within 30 mJ/cm², a highest resolution is less than 20 nm, and an LER/LWR edge roughness is within a resolution of 8%. The current patterning materials cannot satisfy the highest resolution that can be obtained theoretically by the most advanced patterning, which is less than 10 nm. The existing material systems include: organic polymers, small organic molecules, organic metals, organosilicones, and the like. The organic polymer material system is a conventional patterning material. The organic polymer material system is used before a short wavelength less than 15 nm is used. When a wavelength of a light source for patterning is reduced to less than 15 nm, the requirement for resolution of a formed pattern is raised. However, a current limit of a resolution of a pattern formed using the organic polymer material system is about 13 nm. Therefore, a plurality of material systems are explored in the industry. The organosilicone material system has high resolution and small molecular size. However, silicon has low sensitivity to a light source of less than 15 nm, which requires extremely high exposure energy.

As included in the organic metal material system, a metal-organic cluster patterning material has attracted much attention. The cluster material has been researched in various fields for many years, and has a mature material resource library. The metal-organic cluster material is highly sensitive to a light source of less than 15 nm, has a variety of composition elements and methods, has a large size range of molecular clusters for selection, and has a large adjustable range of properties. In particular, using cluster molecules of a size of less than 2 nm has potential advantages of increasing final pattern resolution, reducing edge roughness, and improving sensitivity. The current material library is huge, but the performance of the metal-organic cluster patterning material is not complete, and is still being explored in many ways.

However, in the conventional technology, a metal-organic cluster patterning material that has been developed may cause generation of a gas such as CO₂ after exposure, which pollutes an interior of an exposure machine, making it difficult to implement large-scale industrial production, and adversely affecting resolution and edge roughness of a formed pattern. In addition, in the conventional technology, structural stability and radiation sensitivity of the metal-organic cluster patterning material can still be improved.

### SUMMARY

In view of this, a patterning material is provided. The patterning material has a stable, uniform, flexible, and adjustable structure, has a small molecular size, is highly sensitive to radiation (such as ultraviolet light, X-rays, or electron beams, especially ultraviolet light, X-rays, and electron beams that have a wavelength of less than 15 nm) (for ultraviolet light and X-rays, an exposure energy is less than 200 mJ/cm²; and for electron beams, an exposure energy is less than 100 μC/cm²), and generates almost no harmful gas (that is, excellent low outgassing) during exposure. Therefore, the patterning material may be used as a positive patterning material or a negative patterning material and is suitable for different scenarios, can be exposed to obtain a pattern with high resolution (a resolution of less than 100 nm can be obtained, and a resolution of less than 10 nm can be further obtained), high pattern edge definition (an edge roughness can be obtained as less than 30% of a pattern resolution), and strong etching resistance, and causes almost no gas pollution to a cavity of an exposure device during exposure. In addition, a synthesis method and a synthesis process of the patterning material are simple, which facilitates large-scale production.

A radiation-sensitive patterning composition is further provided, which may be used as a positive patterning composition or a negative patterning composition and is suitable for different scenarios, can be exposed to obtain a pattern with high resolution, high pattern edge definition, and strong etching resistance, and causes almost no gas pollution to a cavity of an exposure device during exposure.

A pattern forming method is further provided, which can efficiently form a pattern with high resolution, high pattern edge definition, and strong etching resistance, and causes almost no gas pollution to a cavity of an exposure device during exposure.

A patterned substrate is further provided, which is suitable for forming a surface structure with high resolution and high pattern edge definition on various substrates in various application scenarios because the patterned substrate includes a patterned film with a pattern having high resolution, high pattern edge definition, and strong etching resistance.

A method for patterning a substrate is further provided, which can obtain a surface structure with high resolution and high pattern edge definition on various substrates because the foregoing patterned substrate is used, and is particularly suitable for producing an integrated circuit with high integration that requires a surface structure with high resolution and high pattern edge definition.

An integrated circuit device is further provided, which can have high integration because a surface structure is formed by using the method for patterning the substrate.

According to a first aspect, an embodiment of this application provides a patterning material, including a metal-oxygen cluster framework formed by a metal M-oxygen bridge bond, a radiation-sensitive organic ligand, and a second ligand.

The radiation-sensitive organic ligand coordinates with the metal M through a coordination atom. The coordination atom is at least one of an oxygen atom, a sulfur atom, a selenium atom, a nitrogen atom, and a phosphorus atom. The radiation-sensitive organic ligand is a monodentate ligand or a polydentate ligand with a denticity of two or more. The second ligand is an inorganic ion or a coordination group.

In this case, the patterning material in this application is a metal-oxygen cluster material, has a stable, uniform, flexible, and adjustable structure, has a small molecular size, is highly sensitive to radiation (such as ultraviolet light, X-rays, or electron beams, especially ultraviolet light, X-rays, and electron beams that have a wavelength of less than 15 nm) (for ultraviolet light and X-rays, an exposure energy is less than 200 mJ/cm²; and for electron beams, an exposure energy is less than 100 μC/cm²), and generates almost no harmful gas (that is, excellent low outgassing) during exposure. Therefore, the patterning material may be used as a positive patterning material or a negative patterning material and is suitable for different scenarios, can be exposed to obtain a pattern with high resolution (a resolution of less than 100 nm can be obtained, and a resolution of less than 10 nm can be further obtained), high pattern edge definition (an edge roughness can be obtained as less than 30% of a pattern resolution), and strong etching resistance, and causes almost no gas pollution to a cavity of an exposure device during exposure. In addition, a synthesis method and a synthesis process of the patterning material are simple, which facilitates large-scale production.

According to the first aspect, in an embodiment, the patterning material is represented by the following general formula (1):

MₓO_{y}(OH)ₙ(L₁)ₐ(L₂)_{b}(L₃)_{c}(L₄)_{d}Xₘ general formula (1)

In the general formula (1), 3≤x≤72, 0≤y≤72, 0≤a≤72, 0≤b≤72, 0≤c≤72, 0≤d≤72, 0≤n≤72, 0≤m≤72, y+n+a+b+c+d+m≤8 x, x, y, a, b, c, d, m, and n are all integers, and a, b, c, and d are not all 0; L₁, L₂, L₃, and L₄ are separately used as the radiation-sensitive organic ligand or are used as the radiation-sensitive organic ligand in a manner in which two or more of L₁, L₂, L₃, and L₄ coexist in a same ligand; and X is the second ligand.

In this case, the patterning material in this application can have a more proper molecular structure, better radiation sensitivity, and/or better low outgassing.

According to the first aspect, in an embodiment, the metal M includes at least one of indium, tin, titanium, vanadium, chromium, manganese, iron, cobalt, nickel, copper, zinc, zirconium, niobium, molybdenum, palladium, platinum, silver, cadmium, antimony, tellurium, hafnium, tungsten, gold, lead, and bismuth.

In this case, the patterning material in this application can have a more stable structure and better radiation sensitivity.

According to the first aspect, in an embodiment, the metal M further includes at least one of sodium, magnesium, aluminum, potassium, calcium, scandium, gallium, germanium, arsenic, rubidium, strontium, yttrium, technetium, ruthenium, rhodium, cesium, barium, lanthanum, cerium, praseodymium, neodymium, promethium, samarium, europium, gadolinium, terbium, dysprosium, holmium, erbium, thulium, ytterbium, lutecium, tantalum, rhenium, osmium, iridium, mercury, and polonium.

In this case, a structure of the patterning material in this application is more flexible and adjustable without losing stability, and has better radiation sensitivity.

According to the first aspect, in an embodiment, the coordination atom is an oxygen atom, and the oxygen atom in the radiation-sensitive organic ligand does not form a carboxyl group or a peroxide bond.

In this case, the patterning material in this application can have a more stable structure and better low outgassing.

According to the first aspect, in an embodiment, the radiation-sensitive organic ligand is formed using at least one of alcohol amine, alcohol, phenol, a nitrogen-containing heterocyclic compound, nitrile, phosphine, phosphonic acid, thiol, and an organic selenium compound.

In this case, the patterning material in this application can have better radiation sensitivity and better low outgassing.

According to the first aspect, in an embodiment, the coordination group is at least one of a halogen group, a carboxylic acid group, a sulfonic acid group, a nitro group, a fatty alcohol group, an aromatic alcohol group, an aliphatic hydrocarbyl group, and an aromatic hydrocarbyl group; and the inorganic ion is at least one of a halogen ion, SO₄²⁻, and NO₃⁻.

In this case, the patterning material in this application can have a more stable structure, better radiation sensitivity, and/or better low outgassing.

According to the first aspect, in an embodiment, L₁, L₂, L₃, and L₄ are respectively derived from at least one of alcohol amine, alcohol, phenol, a nitrogen-containing heterocyclic compound, nitrile, phosphine, phosphonic acid, thiol, and an organic selenium compound.

In this case, the patterning material in this application can have a more stable structure, better radiation sensitivity, and better low outgassing, and can be obtained more easily.

According to the first aspect, in an embodiment, the patterning material is an indium-oxygen cluster material represented by the following general formula (1-1):

[M₄(μ4-O)]ₓ₁Mₓ₂O_{y}(OH)ₙXₘ(L₁)ₐ(L₂)_{b}(L₃)_{c}(L₄)_{d} general formula (1-1)

In the general formula (1-1), M includes at least indium; 1≤x1≤12, 0≤x2≤24, 0≤y≤24, 0≤a≤36, 0≤b≤36, 0≤c≤36, 0≤d≤36, 0≤n≤24, 0≤m≤24, y+n+m+a+b+c+d≤31(x1)+8(x2), x1, x2, y, a, b, c, d, m, and n are all integers, and a, b, c, and d are not all 0; L₁, L₂, L₃, and L₄ are separately used as the radiation-sensitive organic ligand or are used as the radiation-sensitive organic ligand in a manner in which two or more of L₁, L₂, L₃, and L₄ coexist in a same ligand; and X is the second ligand.

The indium-oxygen cluster material in this application has a stable, uniform, flexible, and adjustable structure, and has better radiation sensitivity and better low outgassing.

According to the first aspect, in an embodiment, the radiation-sensitive organic ligand in the indium-oxygen cluster material coordinates with the metal M through a nitrogen atom or an oxygen atom as the coordination atom, and L₁, L₂, L₃, and L₄ are respectively derived from at least one of alcohol amine, alcohol, phenol, a nitrogen-containing heterocyclic compound, and nitrile.

In this case, the indium-oxygen cluster material in this application can be more easily obtained, and has further excellent radiation sensitivity.

According to the first aspect, in an embodiment, at least one X is a halogen ion or a halogen group.

In this case, the indium-oxygen cluster material in this application has particularly excellent radiation sensitivity.

According to the first aspect, in an embodiment, the patterning material is an indium-oxygen cluster material represented by the following general formula (1-11):

[In₄(μ4-O)]ₓ₁Inₓ₂O_{y}(OH)ₙ(L₁)ₐ(L₂)_{b}Xₘ general formula (1-11)

In the general formula (1-11), x1, x2, y, a, b, m, and n are all integers, a and b are not all 0, 1≤x1≤4, 2≤x2≤8, 1≤y≤4, 0≤a≤8, 0≤b≤12, 0≤n≤10, 0≤m≤8, L₁ is OR¹, and L₂ is NR²(CR³R⁴CR⁵R⁶O)₂. R¹, R², R³, R⁴, R⁵, and R⁶ are respectively H, substituted or unsubstituted alkyl with 1 to 18 carbon atoms, substituted or unsubstituted aryl with 6 to 14 carbon atoms, and a substituted or unsubstituted heterocyclic group with 3 to 14 heteroatoms. The heteroatoms in the heterocyclic group include an oxygen atom, a sulfur atom, a nitrogen atom, and a phosphorus atom. X is independently —F, —Cl, or —Br.

Using the indium-oxygen cluster material represented by the general formula (1-11), the foregoing technical effects of this application can be particularly advantageously obtained.

According to the first aspect, in an embodiment, the patterning material is a tin-oxygen cluster material represented by the following general formula (1-2):

MₓO_{y}(L₁)ₐ(L₂)_{b}Xₘ general formula (1-2)

In the general formula (1-2), M includes at least tin; 3≤x≤34, 0≤y≤51, 0≤a≤51, 0≤b≤51, 0≤m≤51, y+a+b+m≤8 x, x, y, a, b, and m are all integers, and a and b are not all 0; L₁ and L₂ are separately used as the radiation-sensitive organic ligand or are used as the radiation-sensitive organic ligand in a manner in which both of L₁ and L₂ coexist in a same ligand; and X is the second ligand.

The tin-oxygen cluster material in this application has a stable, uniform, flexible, and adjustable structure, and has better radiation sensitivity and better low outgassing.

According to the first aspect, in an embodiment, the radiation-sensitive organic ligand in the tin-oxygen cluster material coordinates with the metal M through a nitrogen atom as the coordination atom, and L₁ and L₂ are respectively derived from at least one of alcohol amine, a nitrogen-containing heterocyclic compound, and nitrile.

In this case, the tin-oxygen cluster material in this application can be more easily obtained, and has further excellent radiation sensitivity.

According to the first aspect, in an embodiment, at least one X is a halogen ion or a halogen group.

In this case, the tin-oxygen cluster material in this application has particularly excellent radiation sensitivity.

According to the first aspect, in an embodiment, the patterning material is a tin-oxygen cluster material represented by the following general formula (1-21):

SnₓO_{y}(L₁)ₐXₘ general formula (1-21)

In the general formula (1-21), x, y, a, and m are all integers, 4≤x≤15, 6≤y≤20, 6≤a≤20, and 0≤m≤12. L₁ is independently substituted or unsubstituted pyrazole, substituted or unsubstituted pyridine, substituted or unsubstituted imidazole, substituted or unsubstituted piperazine, or substituted or unsubstituted pyrazine. X is independently —F, —Cl, or —Br.

Using the tin-oxygen cluster material represented by the general formula (1-21), the technical effects of this application can be particularly advantageously obtained.

According to a second aspect, an embodiment of this application provides a radiation-sensitive patterning composition, including the patterning material according to any one of first to sixteenth embodiments of the first aspect and a solvent.

In this case, the radiation-sensitive patterning composition in this application may be used as a positive patterning composition or a negative patterning composition and is suitable for different scenarios, can be exposed to obtain a pattern with high resolution, high pattern edge definition, and strong etching resistance, and causes almost no gas pollution to a cavity of an exposure device during exposure.

According to the second aspect, in an embodiment, the solvent is at least one of carboxylic ester, alcohol with 1 to 8 carbon atoms, aromatic hydrocarbon, halogenated hydrocarbon, and amide.

In this case, the radiation-sensitive patterning composition in this application has better coatability.

According to a third aspect, an embodiment of this application provides a pattern forming method, including the following steps:

A substrate coated with a radiation-sensitive coating is formed. The radiation-sensitive coating includes the patterning material according to any one of first to sixteenth embodiments of the first aspect.

The coated substrate is exposed with radiation according to a required pattern, to form an exposed structure including a region with an exposed coating and a region with an unexposed coating.

The exposed structure is selectively developed to form a patterned substrate with a patterned film.

In this case, by using the pattern forming method in this application, a pattern with high resolution, high pattern edge definition, and strong etching resistance can be formed efficiently, and almost no gas pollution is caused to a cavity of an exposure device during exposure.

According to the third aspect, in an embodiment, the radiation-sensitive coating is formed directly on a silicon wafer or on a silicon wafer covered by an intermediate material layer.

In this case, an integrated circuit device can be obtained efficiently by using the pattern forming method in this application.

According to the third aspect, in an embodiment, the radiation-sensitive coating is formed on the substrate covered by the intermediate material layer by using a coating method.

In this case, the patterned substrate with the patterned film of a more uniform thickness can be obtained, so that the obtained patterned substrate can be more widely used.

According to the third aspect, in an embodiment, the radiation includes X-rays, electron beams, and ultraviolet light.

In this case, an exposure effect can be better implemented, so that a pattern with high resolution, high pattern edge definition, and strong etching resistance can be more easily formed.

According to the third aspect, in an embodiment, a developer used for developing is an aqueous solution developer or an organic solvent developer.

In this case, a developing effect can be better implemented, so that a pattern with high resolution, high pattern edge definition, and strong etching resistance can be more easily formed.

According to a fourth aspect, an embodiment of this application provides a patterned substrate, including a patterned film and a substrate. The patterned film exists in a selected region on the substrate and does not exist in another region on the substrate, and the patterned film is formed using the patterning material according to any one of first to sixteenth embodiments of the first aspect.

In this case, the patterned substrate in this application includes the patterned film with a pattern having high resolution, high pattern edge definition, and strong etching resistance, and is suitable for forming a surface structure with high resolution and high pattern edge definition on various substrates in various application scenarios.

According to the fourth aspect, in an embodiment, a pattern resolution of a pattern of the patterned film is between 3 nm and 100 nm, and an edge roughness is 2% to 30% of the pattern resolution.

In this case, the patterned film included in the patterned substrate in this application can have a pattern with higher resolution and higher pattern edge definition.

According to a fifth aspect, an embodiment of this application provides a method for patterning a substrate, including: performing etching or electron injection on the patterned substrate according to a first or second embodiment of the fourth aspect, to form a patterned structure on a surface of the substrate.

In this case, by using the method for patterning the substrate in this application, a surface structure with high resolution and high pattern edge definition can be obtained on various substrates because the foregoing patterned substrate is used, which is particularly suitable for producing an integrated circuit with high integration that requires a surface structure with high resolution and high pattern edge definition.

According to a sixth aspect, an embodiment of this application provides an integrated circuit device, including a surface structure formed, by using the method for patterning the substrate according to an embodiment of the fifth aspect, on a silicon wafer as the substrate.

In this case, the integrated circuit device in this application can have high integration because the surface structure is formed by using the foregoing method for patterning the substrate.

These aspects and other aspects of this application are more concise and more comprehensive in descriptions of the following (a plurality of) embodiments.

### BRIEF DESCRIPTION OF DRAWINGS

Accompanying drawings included in this specification and constituting a part of this specification and this specification jointly show example embodiments, features, and aspects of this application, and are intended to explain principles of this application.

FIG. 1 is an example flowchart of a patterning process;

FIG. 2 shows example structural formulas of an indium-oxygen cluster material represented by the general formula (1-11) according to an embodiment;

FIG. 3 shows example structural formulas of a tin-oxygen cluster material represented by the general formula (1-21) according to an embodiment;

FIG. 4 is an example manufacturing flowchart of a pattern forming method according to an embodiment;

FIG. 5 is an example manufacturing flowchart of a method for patterning a substrate according to an embodiment;

FIG. 6 is a manufacturing flowchart of an integrated circuit device according to an embodiment;

FIG. 7 is an infrared spectrum of indium-oxygen cluster compounds 1 to 8 according to an embodiment;

FIG. 8 is an EDX spectrum of an indium-oxygen cluster compound 9 according to an embodiment;

FIG. 9 shows a line pattern formed using an indium-oxygen cluster compound 3 according to an embodiment;

FIG. 10 shows a line pattern formed using an indium-oxygen cluster compound 3 according to an embodiment;

FIG. 11 shows a line pattern formed using an indium-oxygen cluster compound 2 according to an embodiment;

FIG. 12 shows a line pattern formed using an indium-oxygen cluster compound 2 according to an embodiment;

FIG. 13 shows a line pattern formed using an indium-oxygen cluster compound 9 according to an embodiment;

FIG. 14 shows a line pattern formed using an indium-oxygen cluster compound 9 according to an embodiment;

FIG. 15 is an infrared spectrum of a tin-oxygen cluster compound 1 according to an embodiment;

FIG. 16 is an infrared spectrum of a tin-oxygen cluster compound 2 according to an embodiment;

FIG. 17 shows a line pattern formed using a tin-oxygen cluster compound 1 according to an embodiment; and

FIG. 18 shows a line pattern formed using a tin-oxygen cluster compound 2 according to an embodiment.

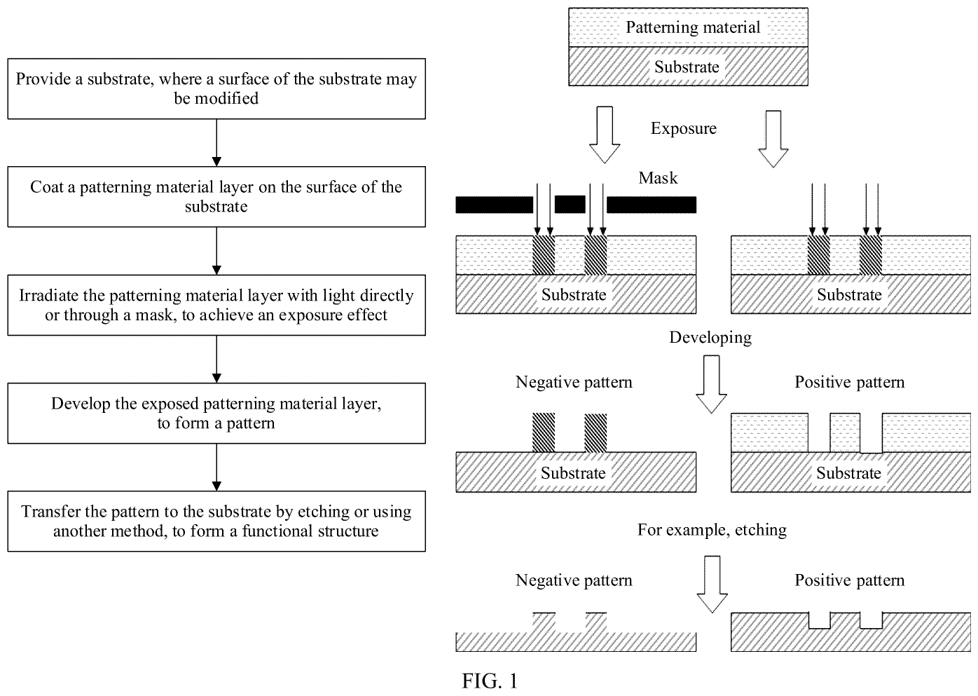

### DETAILED DESCRIPTION

The following describes various example embodiments, features, and aspects of this application in detail with reference to the accompanying drawings. Identical reference numerals in the accompanying drawings indicate elements that have same or similar functions. Although various aspects of embodiments are illustrated in the accompanying drawing, the accompanying drawings are not necessarily drawn in proportion unless otherwise specified.

A specific term “example” herein means “used as an example, embodiment, or illustration”. Any embodiment described as “example” is not necessarily explained as being superior or better than other embodiments.

In addition, to better describe this application, numerous specific details are given in the following embodiments. A person skilled in the art should understand that this application can also be implemented without some specific details. In some examples, methods, means, elements, and circuits that are well-known to a person skilled in the art are not described in detail, so that a subject matter of this application is highlighted.

### First Aspect

To resolve the foregoing technical problems, this application provides a patterning material, including a metal-oxygen cluster framework formed by a metal M-oxygen bridge bond, a radiation-sensitive organic ligand, and a second ligand.

The radiation-sensitive organic ligand coordinates with the metal M through a coordination atom. The coordination atom is at least one of an oxygen atom, a sulfur atom, a selenium atom, a nitrogen atom, and a phosphorus atom. The radiation-sensitive organic ligand is a monodentate ligand or a polydentate ligand with a denticity of two or more. The second ligand is an inorganic ion or a coordination group.

In some embodiments, when the coordination atom is an oxygen atom, the oxygen atom in the radiation-sensitive organic ligand does not form a carboxyl group or a peroxide bond. That “the oxygen atom in the radiation-sensitive organic ligand does not form a carboxyl group or a peroxide bond” means that when the organic ligand coordinates with the metal M using the oxygen atom as the coordination atom, an acyloxy metal structure or a metal peroxide structure is not formed.

The patterning material in this application may be sensitive to various types of radiation (even to the various types of radiation with a specific wavelength or wavelength range) such as ultraviolet light, X-rays, or electron beams based on a specific structure, which means that radiation changes a property of the material, and therefore changes solubility of the material. Specifically, after radiation (exposure), solubility of the exposed material differs greatly from solubility of the unexposed material in a developer, so that the material can be used to form a pattern of a specific form.

The patterning material in this application is a radiation-sensitive metal-oxygen cluster material, which has a small molecular size and a stable and uniform structure due to the metal-oxygen cluster framework (especially represented by the following general formula (1)), and has a flexible and adjustable structure, is sensitive to radiation (for ultraviolet light and X-rays, a material property can be significantly changed with an exposure energy of less than 200 mJ/cm²; and for electron beams, a material property can be significantly changed with an exposure energy of less than 100 μC/cm²), and generates almost no harmful gas (that is, excellent low outgassing) during exposure due to the foregoing specific radiation-sensitive organic ligand and second ligand. Therefore, the patterning material in this application may be used as a positive patterning material or a negative patterning material and is suitable for different scenarios, can be exposed to obtain a pattern with high resolution (a resolution of less than 100 nm can be obtained, and a resolution of less than 10 nm can be further obtained), high pattern edge definition (an edge roughness can be obtained as less than 30% of a pattern resolution), and strong etching resistance, and causes almost no gas pollution to a cavity of an exposure device during exposure. In addition, a synthesis method and a synthesis process of the patterning material in this application are simple, which facilitates large-scale production.

In some embodiments, the patterning material in this application is represented by the following general formula (1):

MₓO_{y}(OH)ₙ(L₁)ₐ(L₂)_{b}(L₃)_{c}(L₄)_{d}Xₘ general formula (1)

In the general formula (1), 3≤x≤72, 0≤y≤72, 0≤a≤72, 0≤b≤72, 0≤c≤72, 0≤d≤72, 0≤n≤72, 0≤m≤72, y+n+a+b+c+d+m≤8 x, x, y, a, b, c, d, m, and n are all integers, and a, b, c, and d are not all 0; L₁, L₂, L₃, and L₄ are separately used as the radiation-sensitive organic ligand or are used as the radiation-sensitive organic ligand in a manner in which two or more of L₁, L₂, L₃, and L₄ coexist in a same ligand; and X is the second ligand.

In this case, the patterning material in this application can have a more proper molecular structure, better radiation sensitivity, and/or better low outgassing.

The metal-oxygen cluster framework and the ligand are described in detail below.

### Metal-Oxygen Cluster Framework

As described above, the metal-oxygen cluster framework in this application is a cluster structure formed by a metal M-oxygen bridge bond. In this case, a specific structure of the metal-oxygen cluster framework is not particularly limited, and may be a mono-metal-oxygen cluster framework or a hetero-metal-oxygen cluster framework with two or more metals, and may be properly changed according to an actual requirement. In some embodiments, a single metal-oxygen cluster is represented by “MₓO_{y}” in the foregoing general formula (1).

In this application, the term “metal M” covers concepts of a metal element and a metalloid element. In some embodiments, the metal M includes at least one of indium (In), tin (Sn), titanium (Ti), vanadium (V), chromium (Cr), manganese (Mn), iron (Fe), cobalt (Co), nickel (Ni), copper (Cu), zinc (Zn), zirconium (Zr), niobium (Nb), molybdenum (Mo), palladium (Pd), platinum (Pt), silver (Ag), cadmium (Cd), antimony (Sb), tellurium (Te), hafnium (Hf), tungsten (W), gold (Au), lead (Pb), and bismuth (Bi). In some embodiments, the metal M includes at least indium or tin.

In some embodiments, the metal M that forms the metal-oxygen cluster framework may further include at least one of sodium (Na), magnesium (Mg), aluminum (Al), potassium (K), calcium (Ca), scandium (Sc), gallium (Ga), germanium (Ge), arsenic (As), rubidium (Rb), strontium (Sr), yttrium (Y), technetium (Tc), ruthenium (Ru), rhodium (Rh), cesium (Cs), barium (Ba), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutecium (Lu), tantalum (Ta), rhenium (Re), osmium (Os), iridium (Ir), mercury (Hg), and polonium (Po).

### Ligand

In this application, both the radiation-sensitive organic ligand (sometimes referred to as a first ligand) and the second ligand are ligands to coordinate with the metal M.

In this application, the first ligand is an organic ligand with radiation sensitivity (for example, sensitivity to ultraviolet light, X-rays, or electron beams, especially ultraviolet light, X-rays, or electron beams with a wavelength of less than 15 nm), and the second ligand may have such radiation sensitivity. Therefore, performance of the patterning material in this application is mainly affected by a structure (especially the coordination atom) of the first ligand. In particular, compared with a ligand containing a metal-carbon bond, a ligand containing a peroxide bond, or a ligand containing a metal-carboxylic acid bond that is used as a radiation-sensitive ligand in the conventional technology, the radiation-sensitive organic ligand in this application can achieve excellent low outgassing while ensuring high radiation sensitivity. For the first ligand, provided that the foregoing requirements for the radiation-sensitive organic ligand (the radiation-sensitive organic ligand coordinates with the metal M through the coordination atom including at least one of an oxygen atom, a sulfur atom, a selenium atom, a nitrogen atom, and a phosphorus atom, and is a monodentate ligand or a polydentate ligand with a denticity of two or more) are satisfied, the patterning material can have the performance expected in this application.

In some embodiments, the radiation-sensitive organic ligand is formed using at least one of alcohol amine, alcohol, phenol, a nitrogen-containing heterocyclic compound, nitrile, phosphine, phosphonic acid, thiol, and an organic selenium compound.

Generally, in this application, a ratio of a quantity of coordination atoms of the radiation-sensitive organic ligand to a quantity of metal atoms is not particularly limited. To further improve radiation sensitivity of the material in this application, and further improve pattern edge definition and resolution of the obtained pattern, in some embodiments, a ratio of a quantity of coordination atoms of the radiation-sensitive organic ligand to a quantity of metal atoms is preferably 1:2 to 4:1.

In some embodiments, when the patterning material in this application is represented by the foregoing general formula (1), L₁, L₂, L₃, and L₄ of the radiation-sensitive organic ligand are preferably respectively derived from at least one of alcohol amine, alcohol, phenol, a nitrogen-containing heterocyclic compound, nitrile, phosphine, phosphonic acid, thiol, and an organic selenium compound.

Alcohol amine is a compound that may be represented by NQ₃ (where at least one Q is a hydrocarbyl group with a hydroxyl group (preferably, an alkyl group with a hydroxyl group), and another Q is independently H or a hydrocarbyl group with 1 to 18 carbon atoms). Examples of alcohol amine include but are not limited to: primary alcohol amine (such as methanolamine, ethanolamine, dimethyl ethanolamine, methyl ethanolamine, and divinylpropanolamine), secondary alcohol amine (such as diethanolamine, methyl diethanolamine, methyl methanol ethanolamine, and ethyl diethanolamine), tertiary alcohol amine (such as triethanolamine, tripropanolamine, and tributanolamine), and the like.

Examples of alcohol include but are not limited to: monohydric alcohol such as methanol, ethanol, propanol, butanol, n-hexanol, and cyclohexanol, polyhydric alcohol such as ethylene glycol, propylene glycol, butylene glycol, glycerol, butanetriol, pentaerythritol, and dipentaerythritol, and the like.

Examples of phenol include but are not limited to: phenol, alkylphenol (such as cresol, ethylphenol, and phenylphenol), alkenylphenol (such as vinylphenol and allylphenol), alkynylphenol (such as acetenylphenol and propinylphenol), and the like.

Examples of the nitrogen-containing heterocyclic compound include but are not limited to: pyridine (substituted or unsubstituted pyridine), pyrazole (substituted or unsubstituted pyrazole), imidazole (substituted or unsubstituted imidazole), piperazine (substituted or unsubstituted piperazine), and pyrazine (substituted or unsubstituted pyrazine). Herein, a substituent in the “substituted or unsubstituted” compound includes but is not limited to: a deuterium atom, a cyano group, and a nitro group; a halogen atom such as a fluorine atom, a chlorine atom, a bromine atom, and an iodine atom; a straight-chain or branched-chain alkyl group such as methyl, ethyl, n-propyl, isopropyl, n-butyl, isobutyl, tert-butyl, n-pentyl, isopentyl, neo-pentyl, and n-hexyl; a straight-chain or branched-chain alkoxy group such as methoxy, ethoxy, and propoxy; an alkenyl group such as vinyl and allyl; an aryloxy group such as phenoxy and tolyloxy; an aryl alkoxy group such as benzyloxy and phenethyloxy; an aromatic hydrocarbyl group or a fused polycyclic aromatic group such as phenyl, biphenyl, triphenyl, naphthyl, anthryl, phenanthryl, fluorenyl, indenyl, pyrenyl, perylenyl, fluoranthyl, and benzophenyl; an aromatic heterocyclic group such as pyridyl, pyrazolyl, pyrazinyl, piperazinyl, imidazolyl, pyrimidyl, triazinyl, thienyl, furyl, pyrryl, quinolyl, isoquinolyl, benzofuryl, benzothiophenyl, indolyl, carbazolyl, benzoxazolyl, benzothiazolyl, quinoxalinyl, benzimidazolyl, dibenzofuranyl, dibenzothiophenyl, and carbinyl; an aryl vinyl group such as styryl and naphthylvinyl; and an acyl group such as acetyl and benzoyl. These substituents may further substitute the foregoing substituents. In addition, these substituents may form a ring by bonding with each other using a single bond, a substituted or unsubstituted methylene group, an oxygen atom, a nitrogen atom, a selenium atom, a phosphorus atom, or a sulfur atom.

Examples of nitrile include but are not limited to: alkyl nitrile such as acetonitrile and propionitrile; alkenyl nitrile such as vinyl nitrile, allyl nitrile, and styryl nitrile; and alkynyl nitrile such as acetenyl nitrile and phenylethynyl nitrile.

Phosphine is a compound that may be represented by PQ₃ (where Q is independently H, a hydrocarbyl group with 1 to 18 carbon atoms, or a hydrocarbonoxy group with 1 to 18 carbon atoms). Examples of phosphine include but are not limited to: monohydrocarbyl phosphine such as methylphosphine dihydride, ethylphosphine dihydride, propylphosphine dihydride, phenylphosphine dihydride, naphthylphosphine dihydride, vinylphosphine dihydride, and acetenylphosphine dihydride; dihydrocarbyl phosphine such as dimethylphosphine hydride, diethylphosphine hydride, dipropylphosphine hydride, dibutylphosphine hydride, methyl ethyl phosphine hydride, methyl pentyl phosphine hydride, methyl phenyl phosphine hydride, diphenylphosphine hydride, divinylphosphine hydride, methyl vinyl phosphine hydride, and diacetylenylphosphine hydride; trihydrocarbyl phosphine such as trimethyl phosphine, triethyl phosphine, tripropyl phosphine, triphenyl phosphine, dimethyl phenyl phosphine, diethyl phenyl phosphine, dipropyl phenyl phosphine, and dibutyl phenoxyphosphine; monohydrocarbonoxy phosphine such as methoxy phosphine dihydride, ethoxy phosphine dihydride, propoxy phosphine dihydride, phenoxy phosphine dihydride, naphthoxy phosphine dihydride, ethyleneoxy phosphine dihydride, and ethynyloxy phosphine dihydride; dihydrocarbyl phosphine such as dimethoxy phosphine hydride, diethoxy phosphine hydride, dipropoxy phosphine hydride, dibutoxy phosphine hydride, methoxy ethoxy phosphine hydride, methoxy pentyloxy phosphine hydride, methoxy phenoxy phosphine hydride, diphenoxy phosphine hydride, diethyleneoxy phosphine hydride, methyl ethyleneoxy hydride, and diethynyloxy phosphine hydride; and trihydrocarbonoxy phosphine such as trimethoxy phosphine, triethoxy phosphine, tripropoxy phosphine, triphenoxy phosphine, dimethyl phenoxy phosphine, diethyl phenoxy phosphine, dipropyl phenoxy phosphine, and dibutoxy phenoxy phosphine.

Examples of phosphonic acid include but are not limited to: butyl phosphonic acid, pentyl phosphonic acid, hexyl phosphonic acid, heptyl phosphonic acid, octyl phosphonic acid, (1-methyl heptyl) phosphonic acid, (2-ethyl hexyl) phosphonic acid, decyl phosphonic acid, dodecyl phosphonic acid, octadecyl phosphonic acid, oleyl phosphonic acid, phenyl phosphonic acid, (p-nonyl phenyl) phosphonic acid, butyl butyl phosphonic acid, pentyl pentyl phosphonic acid, hexyl hexyl phosphonic acid, heptyl heptyl phosphonic acid, octyl octyl phosphonic acid, (1-methyl heptyl) (1-methyl heptyl) phosphonic acid, (2-ethyl hexyl) (2-ethyl hexyl) phosphonic acid, decyl decyl phosphonic acid, dodecyl dodecyl phosphonic acid, octadecyl octadecyl phosphonic acid, oleyl oleyl phosphonic acid, phenyl phenyl phosphonic acid, (p-nonyl phenyl) (p-nonyl phenyl) phosphonic acid, butyl (2-ethyl hexyl) phosphonic acid, (2-ethyl hexyl) butyl phosphonic acid, (1-methyl heptyl) (2-ethyl hexyl) phosphonic acid, (2-ethyl hexyl) (1-methyl heptyl) phosphonic acid, (2-ethyl hexyl) (p-nonyl phenyl) phosphonic acid, and (p-nonyl phenyl) (2-ethyl hexyl) phosphonic acid.

Thiol includes but is not limited to: monothiol such as methanthiol, ethanethiol, propanethiol, butanethiol, n-hexanethiol, and cyclohexanethiol; and polythiol such as ethanedithiol, propanedithiol, butanedithiol, propanetrithiol, butanetrithiol, and butanetetrathiol.

The organic selenium compound includes but is not limited to: organic selenic acid, selenol, selenide, selenophene, hydrocarbyl selenium, hydrocarbonoxy selenium, and the like.

For the second ligand, the second ligand may be any inorganic ion that binds to the metal M through an ionic bond, or may be any coordination group that binds to the metal M through a covalent bond (including a common covalent bond and a coordinate covalent bond).

In some embodiments, when the patterning material in this application is represented by the foregoing general formula (1), the second ligand in the patterning material preferably satisfies X in the general formula (1).

In some embodiments, when the second ligand is a coordination group (that binds to the metal M through a covalent bond), the second ligand is preferably at least one of a halogen group (such as —F, —Cl, —Br, or —I), a carboxylic acid group, a sulfonic acid group, a nitro group, a fatty alcohol group, an aromatic alcohol group, an aliphatic hydrocarbyl group, and an aromatic hydrocarbyl group for flexible coordination. Herein, the term “flexible coordination” means that the ligand may be a monodentate ligand or a polydentate ligand, and a same ligand may be coordinated to same or different metal centers.

In some embodiments, when the second ligand is an inorganic ion (that binds to the metal M through an ionic bond), the second ligand is preferably at least one of a halogen ion (such as F⁻, Cl⁻, Br⁻, or I⁻), SO₄²⁻, and NO₃⁻.

In addition, to further enhance radiation sensitivity, further improve line edge roughness, and further increase resolution, in some embodiments, the radiation-sensitive organic ligand and/or a coordination group as the second ligand may be substituted by any radiation-sensitive functional group. Examples of such radiation-sensitive functional group include but are not limited to a double bond, a triple bond, an epoxypropane group, or a combination thereof.

Moreover, for adjusting performance such as solubility of the patterning material in this application, to further improve thickness uniformity, roughness, adhesion, and corrosion resistance of the patterned film formed using the patterning material in this application, and to further increase pattern resolution of the obtained pattern, in some embodiments, the radiation-sensitive organic ligand and/or a coordination group as the second ligand may be substituted by any functional group. Such functional group includes but is not limited to an electrophilic or electron-donating group, for example, a halogen group such as —F, —Cl, —Br, or —I, a nitro group, a sulfonic acid group, a carboxylic acid group, or an ester group.

The following describes two embodiments of the patterning material in this application in more detail.

### First Embodiment

The patterning material in this application may be more preferably an indium-oxygen cluster material represented by the following general formula (1-1):

[M₄(μ4-O)]ₓ₁Mₓ₂O_{y}(OH)ₙXₘ(L₁)ₐ(L₂)_{b}(L₃)_{c}(L₄)_{d} general formula (1-1)

In the general formula (1-1), M includes at least indium; 1≤x1≤12, 0≤x2≤24, 0≤y≤24, 0≤a≤36, 0≤b≤36, 0≤c≤36, 0≤d≤36, 0≤n≤24, 0≤m≤24, y+n+m+a+b+c+d≤31(x1)+8(x2), x1, x2, y, a, b, c, d, m, and n are all integers, and a, b, c, and dare not all 0.

Herein, the term “M₄(μ4-O)” means that one oxygen (O) atom is bridged to four metals M.

In the general formula (1-1), L₁, L₂, L₃, and L₄ are described as in the general formula (1). Specifically, L₁, L₂, L₃, and L₄ are separately used as the radiation-sensitive organic ligand in this application or are used as the radiation-sensitive organic ligand in this application in a manner in which two or more of L₁, L₂, L₃, and L₄ coexist in a same ligand. In some embodiments, L₁, L₂, L₃, and L₄ are respectively derived from at least one of alcohol amine, alcohol, phenol, a nitrogen-containing heterocyclic compound, nitrile, phosphine, phosphonic acid, thiol, and an organic selenium compound. Herein, the examples of the alcohol amine, alcohol, phenol, nitrogen-containing heterocyclic compound, nitrile, phosphine, phosphonic acid, thiol, and organic selenium compound are also described as above. In addition, L₁, L₂, L₃, and L₄ may be independently substituted by the radiation-sensitive functional group and/or functional group.

Further preferably, the radiation-sensitive organic ligand in the indium-oxygen cluster material of this application coordinates with the metal M through a nitrogen atom or an oxygen atom as the coordination atom, and L₁, L₂, L₃, and L₄ are respectively derived from at least one of alcohol amine, alcohol, phenol, a nitrogen-containing heterocyclic compound, and nitrile.

In the general formula (1-1), X is the second ligand in this application, that is, the inorganic ion or the coordination group. Further preferably, at least one X is a halogen ion or a halogen group, so that the patterning material has particularly excellent radiation sensitivity.

In some embodiments, a ratio of a quantity of coordination atoms (a total quantity of nitrogen atoms and oxygen atoms) to a quantity of metal atoms M is preferably 3:2 to 3:1.

In some embodiments, the patterning material in this application may be particularly preferably an indium-oxygen cluster material represented by the following general formula (1-11):

[In₄(μ4-O)]ₓ₁Inₓ₂O_{y}(OH)ₙ(L₁)ₐ(L₂)_{b}Xₘ general formula (1-11)

In the general formula (1-11), x1, x2, y, a, b, m, and n are all integers, and a and b are not all 0. 1≤x1≤4, preferably x1 is 2; 2≤x2≤8, preferably x2 is 4; 1≤y≤4, preferably, y is 2; 0≤a≤8, 0≤b≤12, preferably, a is 4 and b is 8; 0≤n≤10, preferably, n is 2; and 0≤m≤8, preferably, m is 6.

In the general formula (1-11), L₁ is OR¹, and L₂ is NR²(CR³R⁴CR⁵R⁶O)₂. R¹, R², R³, R⁴, R⁵, and R⁶ are respectively H, substituted or unsubstituted alkyl with 1 to 18 carbon atoms, substituted or unsubstituted aryl with 6 to 14 carbon atoms, and a substituted or unsubstituted heterocyclic group with 3 to 14 heteroatoms (where the heteroatoms include but are not limited to an oxygen atom, a sulfur atom, a nitrogen atom, a phosphorus atom, and the like). Herein, examples of a substituent in the “substituted or unsubstituted” compound are preferably —F, —Cl, —Br, —NO₂, and —SO₃. X is independently —F, —Cl, or —Br.

Using the indium-oxygen cluster material represented by the general formula (1-11), the technical effects of this application can be particularly advantageously obtained.

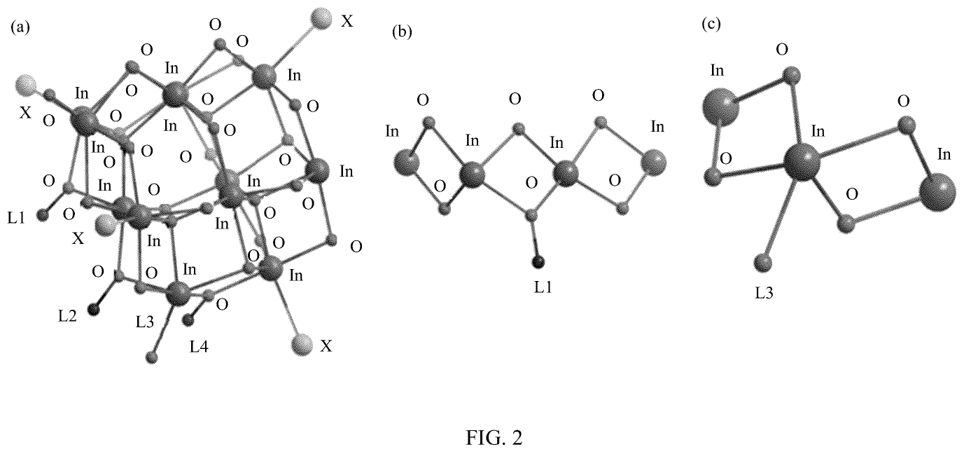

In this application, FIG. 2 shows exemplary structural formulas of the indium-oxygen cluster material represented by the general formula (1-11).

### Second Embodiment

The patterning material in this application may be more preferably a tin-oxygen cluster material represented by the following general formula (1-2):

MₓO_{y}(L₁)ₐ(L₂)_{b}Xₘ general formula (1-2)

In the general formula (1-2), M includes at least tin; 3≤x≤34, 0≤y≤51, 0≤a≤51, 0≤b≤51, 0≤m≤51, y+a+b+m≤8 x, x, y, a, b, and m are all integers, and a and b are not all 0.

In the general formula (1-2), L₁ and L₂ are described as in the general formula (1). Specifically, L₁ and L₂ are separately used as the radiation-sensitive organic ligand in this application or are used as the radiation-sensitive organic ligand in this application in a manner in which both of L₁ and L₂ coexist in a same ligand. In some embodiments, L₁ and L₂ are respectively derived from at least one of alcohol amine, alcohol, phenol, a nitrogen-containing heterocyclic compound, nitrile, phosphine, phosphonic acid, thiol, and an organic selenium compound. Herein, the examples of the alcohol amine, alcohol, phenol, nitrogen-containing heterocyclic compound, nitrile, phosphine, phosphonic acid, thiol, and organic selenium compound are also described as above. In addition, L₁ and L₂ may be independently substituted by the radiation-sensitive functional group and/or functional group.

Further preferably, the radiation-sensitive organic ligand in the tin-oxygen cluster material of this application coordinates with the metal M through a nitrogen atom as the coordination atom, and L₁ and L₂ are respectively derived from at least one of alcohol amine, a nitrogen-containing heterocyclic compound, and nitrile.

In the general formula (1-2), X is the second ligand in this application, that is, the inorganic ion or the coordination group. Further preferably, at least one X is a halogen ion or a halogen group, so that the patterning material has particularly excellent radiation sensitivity.

In some embodiments, a ratio of a quantity of coordination atoms (a total quantity of nitrogen atoms) to a quantity of metal atoms M is preferably 2:3 to 3:2.

In some embodiments, the patterning material in this application may be particularly preferably a tin-oxygen cluster material represented by the following general formula (1-21):

SnₓO_{y}(L₁)ₐXₘ general formula (1-21)

In the general formula (1-21), x, y, a, and m are all integers. 4≤x≤15, preferably, x is 10; 6≤y≤20, preferably, y is 12; 6≤a≤20, preferably, a is 12; and 0≤m≤12, and m is 8.

In the general formula (1-21), L₁ is independently substituted or unsubstituted pyrazole, substituted or unsubstituted pyridine, substituted or unsubstituted imidazole, substituted or unsubstituted piperazine, or substituted or unsubstituted pyrazine. Herein, a substituent in the “substituted or unsubstituted” compound is preferably a straight-chain or branched-chain alkyl group, more preferably, a straight-chain or branched-chain alkyl group with 1 to 4 carbon atoms. Such alkyl group as the substituent may further include a substituent. Examples of the substituent of such alkyl group include but are not limited to —F, —Cl, —Br, —NO₂, and —SO₃. X is independently —F, —Cl, or —Br.

Using the tin-oxygen cluster material represented by the general formula (1-21), the technical effects of this application can be particularly advantageously obtained.

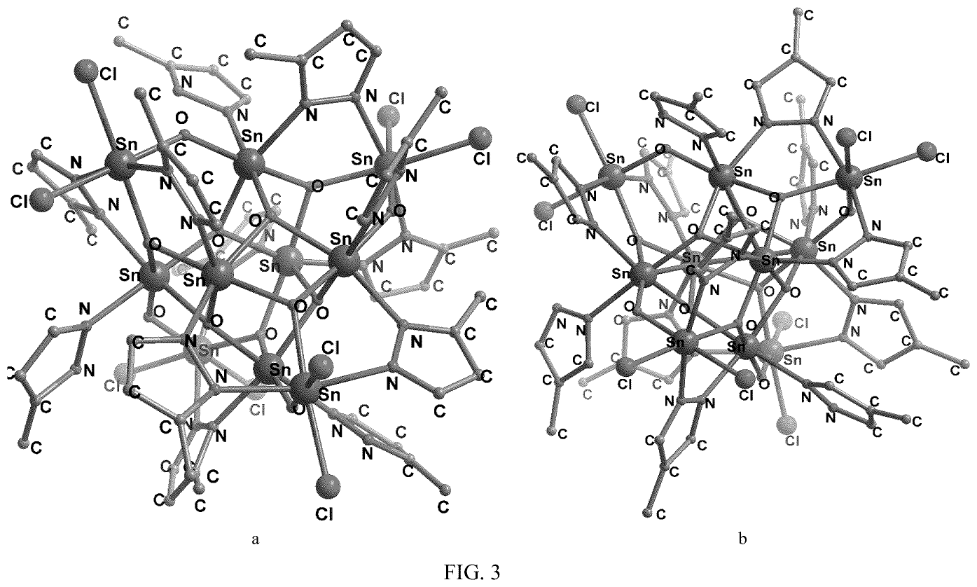

In this application, FIG. 3 shows exemplary structural formulas (a: L=3-methylpyrazole, b: L=4-methylpyrazole) of the tin-oxygen cluster material represented by the general formula (1-21).

### Preparation Method of Patterning Material

The patterning material in this application may be obtained based on a required structure by using a well-known preparation method in the art, without specific limitation.

For example, the patterning material in this application may be obtained by using the following method. MₓXₘ, a precursor (for example, at least one of a compound from which L₁ is derived, a compound from which L₂ is derived, a compound from which L₃ is derived, and a compound from which L₄ is derived) of a radiation-sensitive organic ligand, and an added solvent are mixed and heated to 80° C.-120° C. for one to four days, and then cooled down to room temperature, to precipitate a crystal as a product. In the foregoing method, the precursor of the radiation-sensitive organic ligand may be used as a solvent or as a solute.

In some embodiments, a metal halide including indium halide, at least one of alcohol amine, alcohol, and phenol, and an added solvent are mixed in a reaction kettle, heated to 80° C.-120° C. for one to four days, and then cooled down to a room temperature, to precipitate a colorless crystal as a product.

In some embodiments, a metal halide including tin halide is dissolved in at least one of pyrazole, alcohol amine, pyridine, pyrazole, piperazine, and pyrazine, heated to 80° C.-120° C. for one to four days, and then cooled down to room temperature, to precipitate a colorless crystal as a product.

### Second Aspect

This application further provides a radiation-sensitive patterning composition, including the foregoing patterning material in this application and a solvent.

With the foregoing patterning material in this application included, the radiation-sensitive patterning composition in this application is suitable for different application scenarios, can be exposed to obtain a pattern with high resolution, high pattern edge definition, and strong etching resistance, and causes almost no gas pollution to a cavity of an exposure device during exposure.

The patterning material in this application is described as in the <first aspect>, and details are not described herein again.

Therefore, the following describes in detail components of the radiation-sensitive patterning composition in this application except the patterning material in this application.

### Solvent

In this application, as long as the components of the radiation-sensitive patterning composition can be dissolved, a specific type of a solvent is not particularly limited, and may be properly selected based on thickness and viscosity of a coating film.

In some embodiments, the solvent is at least one of carboxylic ester, alcohol with 1 to 8 carbon atoms, aromatic hydrocarbon, halogenated hydrocarbon, and amide.

Examples of carboxylic ester include but are not limited to: carboxylate ether ester such as ethylene glycol methyl ether formic ester, propylene glycol methyl ether formic ester, ethylene glycol ethyl ether formic ester, propylene glycol ethyl ether formic ester, ethylene glycol methyl ether acetic ester, propylene glycol methyl ether acetic ester, ethylene glycol ethyl ether acetic ester, propylene glycol ethyl ether acetic ester, and ethylene glycol methyl ether propionic ester; and carboxylate alkyl ester such as ethyl formate, methyl acetate, ethyl acetate, n-butyl acetate, n-pentyl acetate, ethyl propionate, ethyl butyrate, ethyl valerate, methyl lactate, ethyl lactate, n-propyl lactate, isopropyl lactate, and n-butyl lactate.

Examples of alcohol with 1 to 8 carbon atoms include but are not limited to: methanol, ethanol, isopropanol, n-butanol, cyclohexanol, and the like.

Examples of aromatic hydrocarbon include but are not limited to: benzene, toluene, xylene, and the like.

Examples of halogenated hydrocarbon include but are not limited to: dichloromethane, trichloromethane, and the like.

Examples of amide include but are not limited to: N,N-dimethylformamide, N,N-dimethylacetamide, and the like.

In some embodiments, the solvent is at least one of ethyl lactate, propylene glycol methyl ether acetic ester, isopropanol, toluene, dichloromethane, N,N-dimethylformamide, and ethyl acetate.

In this application, a concentration of the foregoing patterning material of this application in the radiation-sensitive patterning composition is not particularly limited. A solution concentration may be adjusted based on a requirement of film thickness. In an embodiment, a higher solution concentration corresponds to a thicker film layer. In some embodiments, in the radiation-sensitive patterning composition, a concentration of the patterning material of this application in a solvent is preferably 3 mg/mL-30 mg/mL. When the concentration of the patterning material is within the foregoing range, the thickness of a radiation-sensitive coating obtained using the radiation-sensitive patterning composition can be more uniform and more easily adjusted.

In an embodiment, a range of the concentration may be properly adjusted based on a specific type of the patterning material. In some embodiments, the concentration of the indium-oxygen cluster material of this application in a solvent is more preferably about 5-30 mg/mL. In other embodiments, the concentration of the indium-oxygen cluster material of this application in a solvent is more preferably about 8 mg/mL-30 mg/mL.

### Other Components

In addition to the foregoing patterning material and solvent in this application, without affecting the technical effects of this application, the radiation-sensitive patterning composition in this application may further include other components as required, such as a stabilizer, a dispersant, a sensitizer, a pigment, a dye, an adhesive, a thickener, a thixotropic agent, an anti-precipitation agent, an antioxidant, a pH regulator, a leveling agent, and a plasticizer. These components may be used alone or in a combination of two or more.

Dosages of these components may be properly selected based on actual requirements.

### Use of Radiation-Sensitive Resin Composition

The radiation-sensitive patterning composition in this application may be any positive patterning composition or negative patterning composition, and may be selected properly based on a specific structure of the patterning material.

In this application, the positive patterning composition and the negative patterning composition have respective meanings known in the art. In other words, an exposed patterning material can be washed off by a developer after a radiation-sensitive coating obtained using the positive patterning composition is developed, to form a positive pattern; and an unexposed patterning material can be washed off by a developer after a radiation-sensitive coating obtained using the negative patterning composition is developed, to form a negative pattern.

In this application, preferably, the radiation-sensitive patterning composition in this application is a negative patterning composition.

In this application, there is no special limitation on use of the radiation-sensitive patterning composition, for example, preparing a passivation film, an interlayer insulation film, a surface protection film, an insulation film for redistribution, and the like of a semiconductor element, a display body apparatus, a light-emitting apparatus, and the like.

Particularly, due to excellent performance, in some embodiments, the patterning material in this application is particularly suitable for obtaining a fine pattern with a pattern resolution of 3 nm-100 nm and an edge roughness of 2%-30% of the pattern resolution.

### Third Aspect

This application further provides a pattern forming method, including the following steps: A substrate coated with a radiation-sensitive coating is formed. The radiation-sensitive coating includes the foregoing patterning material of this application. The coated substrate is exposed with radiation according to a required pattern, to form an exposed structure including a region with an exposed coating and a region with an unexposed coating. The exposed structure is selectively developed to form a patterned substrate with a patterned film.

By using the pattern forming method in this application, a pattern with high resolution, high pattern edge definition, and strong etching resistance can be formed efficiently, and almost no gas pollution is caused to a cavity of an exposure device during exposure.

In addition, an application scenario of the pattern forming method is not particularly limited, and may be in a process of manufacturing a semiconductor element, a display body apparatus, or a light-emitting apparatus as required.

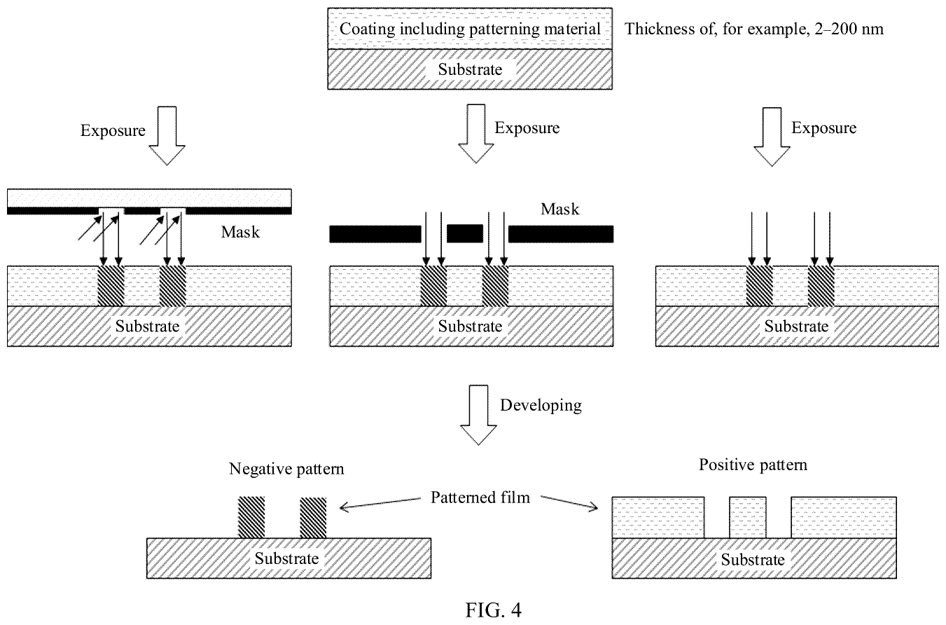

FIG. 4 is an exemplary manufacturing flowchart of the pattern forming method according to this application (an intermediate material layer is not shown). The following describes the steps in detail.

### Form a Coated Substrate

In this step, a substrate coated with a radiation-sensitive coating is formed. The radiation-sensitive coating includes the foregoing patterning material of this application.

Details of the patterning material of this application are described as in the <first aspect>, and the details are not described herein again.

In this step, a type of the substrate is not particularly limited, and may be synthetic resin such as polyethylene terephthalate, polyethylene naphthalate, polyethylene, polycarbonate, cellulose triacetate, cellophane, polyimide, polyamide, polyphenylene sulfide, polyetherimide, polyether sulfone, aromatic polyamide, or polysulfone; a semiconductor substrate such as a silicon wafer; a wiring substrate; glass; metal such as copper, titanium, or aluminum; or ceramic. In addition, a form of the substrate is not particularly limited, and may be any object on which a patterned film needs to be formed and may have any shape.

In some embodiments, the substrate is a silicon wafer.

In this step, a surface of the substrate may be pretreated or not pretreated as required. Examples of a method for pretreating the surface of the substrate include but are not limited to: washing with a neutral liquid (for example, water, or an organic solvent such as ethanol or toluene), washing with an acid liquid, washing with an alkaline liquid, corona treatment, electroplating, electroless plating, prime coating, and vapor deposition. These method examples may be used alone or in a combination of two or more.

In some embodiments, the substrate is preferably pretreated to be hydrophilic or hydrophobic before the radiation-sensitive coating is formed.

In some embodiments, the substrate is preferably a silicon wafer, and a surface of the silicon wafer is preferably treated to be hydrophilic. For example, examples of hydrophilic treatment include but are not limited to: wash the silicon wafer in a Piranha solution (H₂O:30% aqueous ammonia:30% H₂O₂=5:1:1) for 15 minutes-20 minutes, wash the silicon wafer with deionized water, then wash the silicon wafer with alcohol such as methanol, ethanol, and isopropanol, and then blow the liquid away from the surface.

In other embodiments, the substrate is preferably a silicon wafer, and a surface of the silicon wafer is preferably treated to be hydrophobic. For example, examples of hydrophobic treatment include but are not limited to: uniformly coating a silazane compound such as hexamethyldisilazane (HMDS) on a hydrophilically treated surface of the silicon wafer by vapor deposition or coating (preferably, spin coating).

In this step, for the coated substrate, the radiation-sensitive coating in this application may be directly formed on the substrate, or may be formed on the substrate on which an intermediate material layer is pre-formed. Herein, examples of the intermediate material layer include but are not limited to an anti-reflective layer, an anti-etching layer, and an absorption layer. These examples of the intermediate material layer are well known in the art. For example, examples of the anti-reflective layer include but are not limited to: a bottom anti-reflective layer (BARC, Bottom anti-reflective coating), a spin-coated silicon compound layer (SOC, Spin on glass), a spin-coated carbon compound layer (SOG, Spin on carbon), or the like. In addition, these examples of the intermediate material layer may be used as a single layer or as two or more layers.

In some embodiments, the substrate is preferably a silicon wafer, and the radiation-sensitive coating is directly formed on the silicon wafer. In other embodiments, the substrate is preferably a silicon wafer. Before the radiation-sensitive coating is formed, an intermediate material layer, such as an anti-reflective layer, an anti-etching layer, or an absorption layer, may be formed on a surface of the silicon wafer.

In this step, the method for forming the radiation-sensitive coating is not particularly limited, and various methods well known in the art may be used. In some embodiments, the radiation-sensitive coating is formed by using a coating method. In some embodiments, the radiation-sensitive coating is formed on the substrate covered by the intermediate material layer by using a coating method, and more specifically, the radiation-sensitive coating may be formed on the silicon wafer covered by the intermediate material layer by using the coating method.

In some embodiments, the radiation-sensitive coating is formed by coating the foregoing radiation-sensitive patterning composition of this application. Details of the radiation-sensitive patterning composition of this application are described as in the <second aspect>, and the details are not described herein again.

In this step, the coating method may be known in the art. Examples of such coating method include but are not limited to: dip coating, spin coating, rod coating, blade coating, curtain coating, screen-printing coating, spray coating, slit coating, and the like. These method examples may be used alone or in a combination of two or more. In some embodiments, the coating method is preferably spin coating, spray coating, dip coating, or blade coating, more preferably spin coating.

In this step, after the coating, drying may be performed. The drying is performed without particular limitation, and may be performed by using a drying method known in the art.

In this step, after the drying, baking may be performed to remove residual solvent. In an embodiment, baking conditions are changed according to specific types of the metal-oxygen cluster material and the solvent that are used. In some embodiments, a baking temperature is preferably and a baking time is preferably 20 seconds-120 seconds.

In some embodiments, a thickness of the formed radiation-sensitive coating is preferably 2 nm-200 nm, more preferably 5 nm-180 nm. In other embodiments, a surface roughness of the formed radiation-sensitive coating is less than 2 nm.

In some embodiments, this step is performed by the following step. A 4-inch silicon wafer is spin-coated, for example, with 1 mL-5 mL of the patterning material, to obtain a radiation-sensitive coating with any uniform thickness of 2 nm-200 nm. A surface roughness of the radiation-sensitive coating is less than 2 nm.

### Expose the Coated Substrate

In this step, the coated substrate is exposed with radiation according to a required pattern, to form an exposed structure including a region with an exposed coating and a region with an unexposed coating.

In this step, the exposure is not particularly limited, and may be performed in various forms known in the art. In some embodiments, for example, the coated substrate is exposed directly with radiation. In other embodiments, the coated substrate is exposed with radiation through a mask.

Herein, the term “through a mask” means that the radiation for exposure is modified by the mask. However, there is no limitation on the modification manner, for example, the radiation may pass through the mask, or the radiation may be reflected on the mask.

Herein, a structure of the mask is not particularly limited. The mask may or may not include a patterning hollow portion; and may or may not include a reflection portion.

In this step, there is no special limitation on a type of the radiation for exposure, provided that solubility of the patterning material in this application can be changed. The patterning material of this application may be sensitive to various types of radiation with a specific wavelength or wavelength range based on its specific structure, and may exhibit different solubility changes. In some embodiments, in the exposed structure, the exposed coating (including the exposed patterning material of this application) may be removed in a subsequent developing process, to perform positive developing. In other embodiments, the unexposed coating (including the unexposed patterning material of this application) may be removed in a subsequent developing process, to perform negative developing.

In some embodiments, the radiation for exposure is preferably ultraviolet light, X-rays, or electron beams. In some embodiments, the coated substrate is exposed with ultraviolet light or X-rays through a mask. In other embodiments, the coated substrate is directly exposed with electron beams.

In some embodiments, the radiation for exposure is more specifically ultraviolet light, X-rays, or electron beams with a wavelength of less than 15 nm, and is further more specifically ultraviolet light with a wavelength of less than 15 nm and within an ultraviolet light range, soft X-rays within an X-ray range, or electron beams.

In some embodiments, an exposure apparatus may be any apparatus known in the art, such as a contact aligner, a mirror projector, a stepper, a laser direct exposure apparatus, an X-ray exposure machine, or an electron accelerator.

In this step, exposure energy is not particularly limited. The patterning material in this application has excellent radiation sensitivity. As described above, for ultraviolet light and X-rays, an exposure effect can be achieved with an exposure energy of less than 200 mJ/cm²; and for electron beams, an exposure effect can be achieved with an exposure energy of less than 100 μC/cm². In some embodiments, for ultraviolet light and X-rays, the exposure energy is preferably less than 100 mJ/cm², more preferably less than 30 mJ/cm². In some embodiments, for electron beams, the exposure energy is less than 80 μC/cm².

In this step, after exposure, baking may be performed to promote chemical reaction in the coating. In an embodiment, baking conditions are changed according to a specific type of the used metal-oxygen cluster material. In some embodiments, a baking temperature is preferably 60° C.-200° C., and a baking time is preferably 20 seconds-120 seconds.

### Developing

In this step, the exposed structure is selectively developed to form a patterned substrate with a patterned film.

In some embodiments, when the patterning material in this application is a positive patterning material, the developing may be selectively performed to remove the exposed coating from the exposed structure. In some embodiments, when the patterning material in this application is a negative patterning material, the developing may be selectively performed to remove the unexposed coating from the exposed structure.

In this step, the developing is not particularly limited, and may be performed by using a developing method known in the art. In some embodiments, the developing is performed by contacting a developer with the exposed structure.

In this step, the contact with the developer is not particularly limited, and may be performed by using a method for applying the developer known in the art. Examples of such method include but are not limited to: dip coating (e.g., may be performed under ultrasonic irradiation), spin coating, spray coating, and the like. These method examples may be used alone or in a combination of two or more.

When a developer is used, a quantity of times of contact between the developer and the exposed structure is not particularly limited, and may be only one or may be two or more. Each time of contact may be performed using a same developer or different developers.

When a developer is used, a specific type of the developer is not particularly limited, and may be properly selected based on a specific type of the patterning material. In some embodiments, the developer is preferably an aqueous solution developer or an organic solvent developer.

In some embodiments, the aqueous solution developer is preferably an aqueous alkaline solution. Examples of an alkaline substance included in the aqueous alkaline solution include but are not limited to: inorganic alkaline such as sodium hydroxide, sodium carbonate, sodium silicate, and aqueous ammonia; organic amine such as ethylamine, diethylamine, triethylamine, and triethanolamine; quaternary ammonium salt such as tetramethyl ammonium hydroxide and tetrabutyl ammonium hydroxide; and the like. More preferably, the aqueous solution developer is an aqueous tetramethyl ammonium hydroxide solution with a concentration of 0.5 wt %-5 wt %.

In other embodiments, an organic solvent included in the organic solvent developer is at least one of a ketone solvent, an alcohol solvent, an ether solvent, an ester solvent, and an amide solvent. In addition, the organic solvent developer may or may not be aqueous. When a plurality of organic solvents (aqueous) are included, proportions of the organic solvents (aqueous) are not particularly limited, and may be properly adjusted according to actual requirements.

Specific examples of the ketone solvent include but are not limited to, for example, cyclopentanone, cyclohexanone, and methyl-2-n-pentanone.

Specific examples of the alcohol solvent include but are not limited to, for example, monohydric alcohol such as methanol, ethanol, isopropanol, 3-methoxybutanol, 3-methyl-3-methoxybutanol, 1-methoxy-2-propanol, 1-ethoxy-2-propanol, and diacetone alcohol; and polyhydric alcohol such as diethylene glycol, propylene glycol, glycerol, 1,4-butylene glycol, or 1,3-butylene glycol.

Specific examples of the ether solvent include but are not limited to, for example, propylene glycol monomethyl ether, ethylene glycol monomethyl ether, propylene glycol monoethyl ether, ethylene glycol monoethyl ether, propylene glycol dimethyl ether, and diethylene glycol dimethyl ether.

Specific examples of the ester solvent include but are not limited to, for example, chain ester such as propylene glycol methyl ether acetate (PGMEA), propylene glycol monoethyl ether acetate, methyl lactate, ethyl lactate, n-propyl lactate, isopropyl lactate, n-butyl lactate, ethyl pyruvate, butyl acetate, 3-ethoxypropionic acid methyl ester, 3-ethoxypropionic acid ethyl ester, tertbutyl acetate, tertbutyl propionate, and propylene glycol monotertbutyl ether acetate; and lactone such as γ-butyrolactone.

Examples of the amide solvent include but are not limited to: N,N-dimethylformamide, N,N-dimethylacetamide, and the like.

In some embodiments, when the indium-oxygen cluster material in this application is used, the developer includes an alcohol solvent, an ester solvent, an amide solvent, or a combination thereof, and more specifically includes isopropanol, N,N-dimethylformamide, propylene glycol methyl ether acetate, or a combination thereof. More preferably, the developer is a mixture of N,N-dimethylformamide and propylene glycol methyl ether acetate (PGMEA) (in a volume ratio of 10:1 to 1:10) or a mixture of isopropanol and PGMEA (in a volume ratio of 10:1 to 1:10).

In some embodiments, when the tin-oxygen cluster material in this application is used, the developer includes an alcohol solvent, an ester solvent, an amide solvent, water, or a combination thereof, and more specifically includes isopropanol, N,N-dimethylformamide, propylene glycol methyl ether acetate, ethyl lactate, water, or a combination thereof. More preferably, the developer is a mixture of isopropanol and water (in a volume ratio of 10:1 to 1:10) or a mixture of isopropanol and PGMEA (in a volume ratio of 10:1 to 1:10).

In addition, in some embodiments, the developer may further include a surfactant, a viscosity reducer, and the like in any content as required.

When a developer is used, a contact time (developing time) of the developer and the exposed structure is not particularly limited, and may be properly selected based on a specific structure of the metal-oxygen cluster material. In an embodiment, the contact time is preferably 10 seconds to 10 minutes, more preferably 10 seconds to 300 seconds.

In some embodiments, when the indium-oxygen cluster material in this application is used, the contact time is preferably 10 seconds to 120 seconds, more preferably 15 seconds to 60 seconds.

In other embodiments, when the tin-oxygen cluster material in this application is used, the contact time is preferably 10 seconds to 10 minutes, more preferably 15 seconds to 60 seconds.

In some embodiments, after the developing, rinsing with water may be performed. In an embodiment, rinsing conditions are changed according to a specific type of the used metal-oxygen cluster material and a developing method (such as a type of a developer and a method for applying the developer). In some embodiments, a rinsing time is preferably 10 s to 120 s. In some embodiments, a rinsing temperature is preferably ambient temperature.

In some embodiments, after the developing, baking may be performed. In an embodiment, baking conditions are changed according to a specific type of the used metal-oxygen cluster material and a developing method (such as a type of a developer and a method for applying the developer). In some embodiments, a baking temperature is preferably 60° C.-200° C., and a baking time is preferably 20 seconds-120 seconds.

Particularly, because the foregoing patterning material in this application has excellent performance, the pattern forming method in this application is particularly suitable for obtaining a fine pattern with a pattern resolution of less than 100 nm (preferably between 3 nm and 100 nm) and an edge roughness of less than 30% (preferably, 2%-30%) of the pattern resolution.

### Other Steps

In this application, the pattern forming method of this application may further include other steps as required. Examples of other steps include but are not limited to a washing step, a drying step, and the like.

In some embodiments, the substrate is washed and/or dried before the radiation-sensitive coating is formed (if there is pretreatment, before the pretreatment).

In some embodiments, after the developing step, the formed patterned film is washed and/or dried.

### Fourth Aspect

This application further provides a patterned substrate, including a patterned film and a substrate. The patterned film exists in a selected region on the substrate and does not exist in another region on the substrate, to form a pattern on the substrate, and is formed using the foregoing patterning material in this application.

Herein, that “formed using the foregoing patterning material in this application” means that the patterned film is formed using at least the foregoing patterning material in this application as a raw material. In some embodiments, the patterned film includes at least an exposed patterning material. In other embodiments, the patterned film includes at least an unexposed patterning material.

The patterned substrate in this application can include the patterned film with a pattern having high resolution, high pattern edge definition, and strong etching resistance.

In addition, the patterned substrate in this application may include an intermediate material layer between the patterned film and the substrate. In some embodiments, the patterned substrate in this application includes an intermediate material layer between the patterned film and the substrate.

In this application, a method for forming the patterned substrate is not particularly limited, and various methods known in the art may be used. In some embodiments, the patterned substrate is formed by using the foregoing pattern forming method in this application.

Details of the patterning material, the intermediate material layer, the substrate, and the pattern forming method in this application are respectively described as in the first aspect and the third aspect, and the details are not described herein again.

In this application, resolution and edge roughness of the pattern of the patterned film on the patterned substrate are not particularly limited. In this application, as described above, the patterned film can have a high resolution of less than 100 nm, and can have high pattern edge definition with an edge roughness of less than 30% of the pattern resolution. In this application, the resolution and the edge roughness of the pattern of the patterned film may be measured by a scanning electron microscope.

In some embodiments, the resolution of the pattern formed on the patterned film of the patterned substrate is preferably 3 nm-100 nm, more preferably 3 nm-50 nm, further preferably 3 nm-20 nm, particularly preferably 3 nm-10 nm.

In some embodiments, the edge roughness of the pattern formed on the patterned film of the patterned substrate is preferably 2%-30% of the pattern resolution, more preferably 2%-8% of the pattern resolution.

In this application, the pattern formed on the patterned film is not particularly limited, and may be designed randomly according to an actual requirement.

### Fifth Aspect

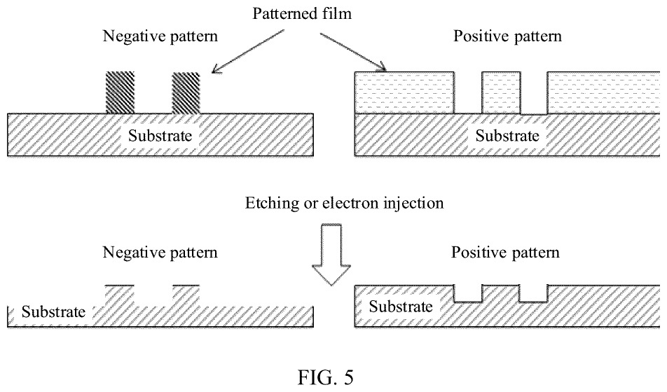

This application further provides a method for patterning a substrate, including: performing etching or ion implantation on the foregoing patterned substrate in this application, to form a patterned structure on a surface of the substrate. FIG. 5 is an exemplary manufacturing flowchart of the method for patterning the substrate according to this application (where an intermediate material layer is not shown).

In this application, the etching and the ion implantation are not particularly limited, and may be performed by using various methods known in the art.

In some embodiments, the etching is preferably performed. In this application, etching conditions are not particularly limited, and may be changed according to a process requirement, etching selectivity, and an etching rate. In some embodiments, examples of etching gas include but are not limited to Cl₂+O₂, HBr+Cl₂, SF₆, CF₄+O₂, CHF₃+O₂, and BCl₃. In addition, in some embodiments, an etching selection ratio of a relative matching layer material such as Barc to a substrate material such as SiO₂ is between 10:1 and 1:10.

In this application, the patterned structure formed on the substrate is not particularly limited, may be designed randomly according to a requirement, and may depend on a specific pattern of the patterned film of the used patterned substrate.

### Sixth Aspect

This application further provides an integrated circuit device, including a surface structure formed, by using the foregoing method for patterning the substrate in this application, on a silicon wafer as the substrate.

In this application, a specific type of the integrated circuit device is not particularly limited. In some embodiments, the integrated circuit device in this application may be used in various terminals such as a tablet computer, a notebook computer, a digital camera, a mobile phone, a wearable electronic device, and a virtual reality device.

In this application, the surface structure is not particularly limited, may be designed randomly according to a requirement, and may depend on a specific pattern of the patterned film of the patterned substrate used in the foregoing method for patterning the substrate in this application.

### Specific Example

In some embodiments, a method for manufacturing an integrated circuit device (or a preformed part of the integrated circuit device) in this application is performed as follows.

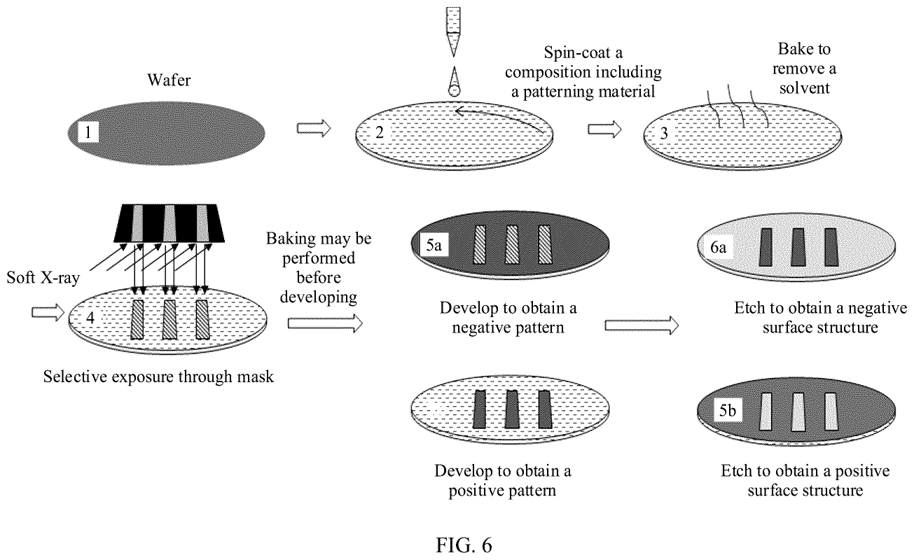

First, a metal-oxygen cluster material is dissolved in a proper solvent to form a solution. According to a size of a substrate, the solution of any volume is spin-coated on a silicon wafer or a silicon wafer covered by an intermediate material layer, to form a patterning material film layer with a thickness of less than less than 100 nm, as shown in FIG. 6(1,2). Before exposure, the residual solvent may be removed from the film layer through baking, as shown in FIG. 6(3).

Then, the patterning material film layer is selectively irradiated with any single-wavelength rays or mixed-wavelength rays in a range of 1 nm-15 nm Soft X-ray (soft X-ray) through reflection of a mask, and a pattern on the mask is transferred to the patterning material film layer, as shown in FIG. 6(4).

The patterning material film layer that is irradiated is washed with a developer to perform developing for 10 s to 300 s.

In the patterning material film layer obtained through the developing, if an irradiated part is not washed off, a negative pattern is formed, and the patterning material is referred to as a negative patterning material, as shown in FIG. 6(5a); or if an irradiated part is washed off, a positive pattern is formed, and the patterning material is referred to as a positive patterning material, as shown in FIG. 6(5b).

The pattern formed by the patterning material has a selective protection effect on the substrate (the silicon wafer or the silicon wafer covered by the intermediate material layer) in an etching step. After etching, the patterning material and an unprotected region of the substrate are etched off, but a protected region by the patterning material is etched slower than the unprotected region, to finally form a pattern on the substrate. FIG. 6(6a) is a negative pattern, and FIG. 6(6b) is a positive pattern.

### EXAMPLE

The following describes examples of this application in detail, but this application is not limited to the following examples.

### Example 1: Based on Radiation-Sensitive Indium-Oxygen Cluster Material

### Example 1-1: Synthesis of Radiation-Sensitive Indium-Oxygen Cluster Material

The following radiation-sensitive indium-oxygen cluster materials were prepared.

Indium-oxygen cluster compound 1: [{In₄(μ4-O)}₂In₄O₂(OH)₂(L₁)₄(L₂)₈X₆] (L₁=OR¹, R¹=C₆H₅; L₂=NH(CH₂CH₂O)₂; X=Cl).

Synthesis method: InX₃ (1 mmol, X=Cl) was dissolved in a mixture of 2 mL-3 mL of phenol and 1 mL of diethanolamine, heated to 100° C. for two days, and then cooled down to room temperature, to precipitate a colorless crystal.

Indium-oxygen cluster compounds 2 and 3: [{In₄(μ4-O)}₂In₄O₂(OH)₂(L₁)₄(L₂)₈X₆] (L₁=OR¹, R¹=CH₃; L₂=NH(CH₂CH₂O)₂; X=Cl (compound 3), Br (compound 2)).

Synthesis method: InX₃ (1 mmol, X=Cl or Br) was dissolved in a mixture of 3-4 mL of CH₃OH and 1 mL of diethanolamine, heated to 100° C. for two days, and then cooled down to room temperature, to precipitate a colorless crystal as a product.

Indium-oxygen cluster compounds 4 to 9: [{In₄(μ4-O)}₂In₄O₂(OH)₂(L₁)₄(L₂)₈X₆] (L₁=OR¹, R¹=C₆H₄Cl; L₂=NH(CH₂CH₂O)₂; X=Br), [{In₄(μ4-O)}₂In₄O₂(OH)₂(L₁)₄(L₂)₈X₆] (L₁=OR¹, R¹=C₆H₄Cl; L₂=NH(CH₂CH₂O)₂; X=Cl) [{In₄(μ4-O)}₂In₄O₂(OH)₂(L₁)₄(L₂)₈X₆] (L₁=OR¹, R¹=C₆H₄F; L₂=NH(CH₂CH₂O)₂; X=Br), [{In₄(μ4-O)}₂In₄O₂(OH)₂(L₁)₄(L₂)₈X₆] (L₁=OR¹, R¹=C₆H₄F; L₂=NH(CH₂CH₂O)₂; X=Cl), [{In₄(μ4-O)}₂In₄O₂(OH)₂(L₁)₄(L₂)₈X₆] (L₁=OR¹, R¹=C₆H₄NO₂; L₂=NH(CH₂CH₂O)₂; X=Br), [{In₄(μ4-O)}₂In₄O₂(OH)₂(L₁)₄(L₂)₈X₆] (L₁=OR¹, R¹=C₆H₄NO₂; L₂=NH(CH₂CH₂O)₂; X=Cl).

Synthesis method: InX₃ (1 mmol, X=Cl, Br) and R¹OH (5 mmol, R¹=C₆H₄F, C₆H₄Cl, or C₆H₄NO₂) were dissolved in a mixture of 3 mL of tetrahydrofuran and 1 mL of diethanolamine, heated to 100° C. for two days, and then cooled down to room temperature, to precipitate a crystal.

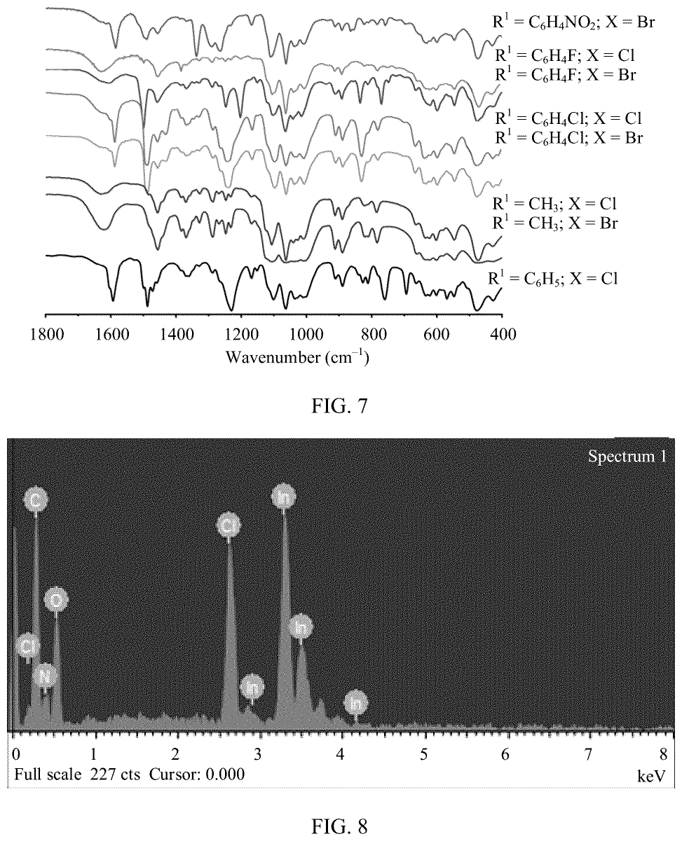

The indium-oxygen cluster compounds 1 to 8 were represented by infrared analysis of solids, to obtain an infrared spectrum by using Bruker VERTEX 70, as shown in FIG. 7. In addition, an EDX spectrum of the indium-oxygen cluster compound 9 was obtained by using JEOL JSM6700F+Oxford INCA, as shown in FIG. 8.

### Example 1-2: Pattern Forming Method Using Radiation-Sensitive Indium-Oxygen Cluster Material

### (1) Pretreatment of Silicon Wafer

Hydrophilic treatment: A silicon wafer was washed in a Piranha solution (H₂O:30% aqueous ammonia:30% H₂O₂=5:1:1) for 15-20 minutes, then washed with deionized water and then with isopropanol. Before use, the liquid was blown away from the surface of the silicon wafer by using an air syringe.

Hydrophobic treatment: The surface of the silicon wafer obtained through the hydrophilic treatment was covered uniformly by HMDS by vapor deposition or spin coating.

### (2) Coating

5 mg-20 mg of each of the indium-oxygen cluster compounds 1 to 8 was dissolved in 1 mL of N,N-dimethylformamide (DMF), prior to filtering. A proper amount of filtered solution (negative patterning composition) was spin-coated on the hydrophilic or hydrophobic surface of the silicon wafer to form an indium-oxygen cluster patterning material coating.

### (3) Exposure

Exposure with radiation: The indium-oxygen cluster patterning material coating was exposed by using an electron-beam etching technology (EBL).

### (4) Developing

A developer includes a mixture of DMF and propylene glycol methyl ether acetate (PGMEA) (in a volume ratio of 10:1 to 1:10) and a mixture of isopropanol (IPA) and PGMEA (in a volume ratio of 10:1 to 1:10). A developing time is 15 s to 60 s.

### (5) Pattern Representation

Each patterned substrate obtained through the developing was represented by using a scanning electron microscope (SEM). The resolution obtained can reach 100 nm or even 50 nm. Details are as follows:

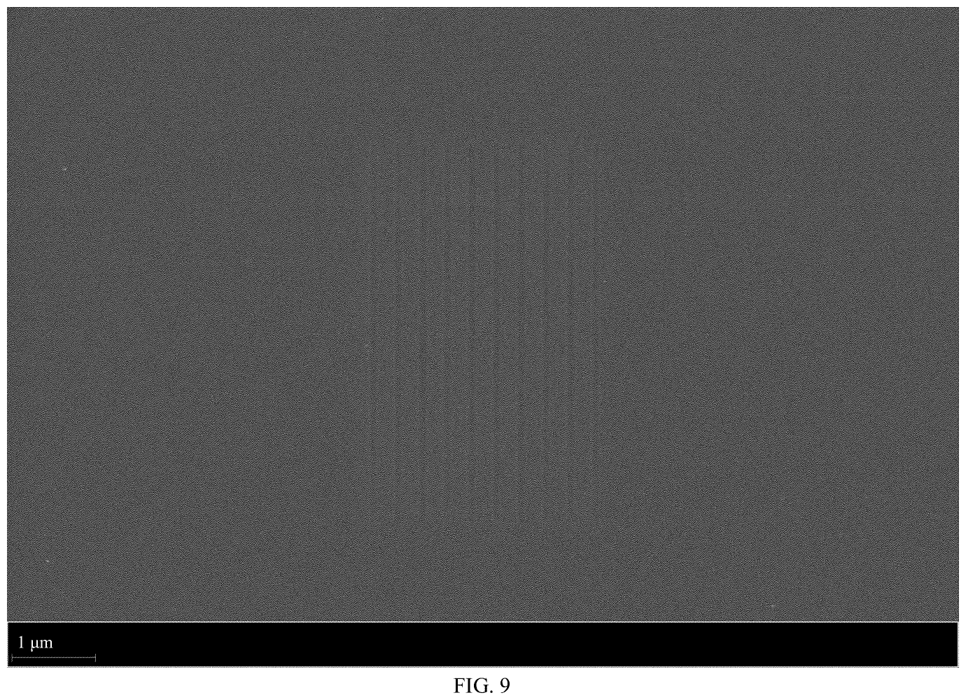

After the patterned substrate is formed using the indium-oxygen cluster compound 3, a width of a line represented and exposed by using the SEM is 100 nm, as shown in FIG. 9.

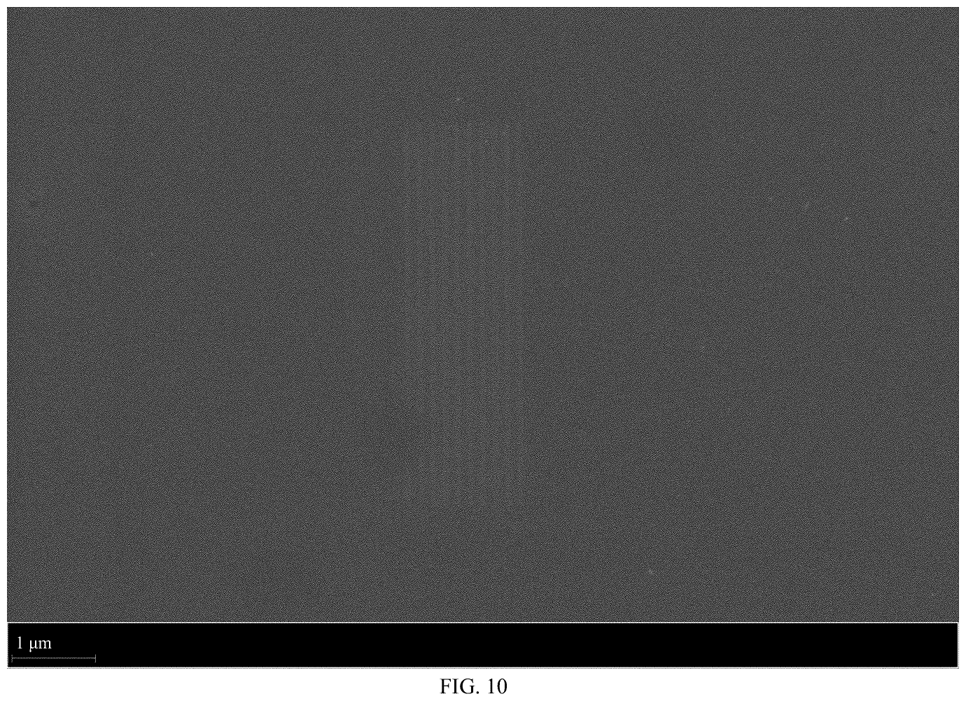

After the patterned substrate is formed using the indium-oxygen cluster compound 3, a width of a line represented and exposed by using the SEM is 50 nm, as shown in FIG. 10.

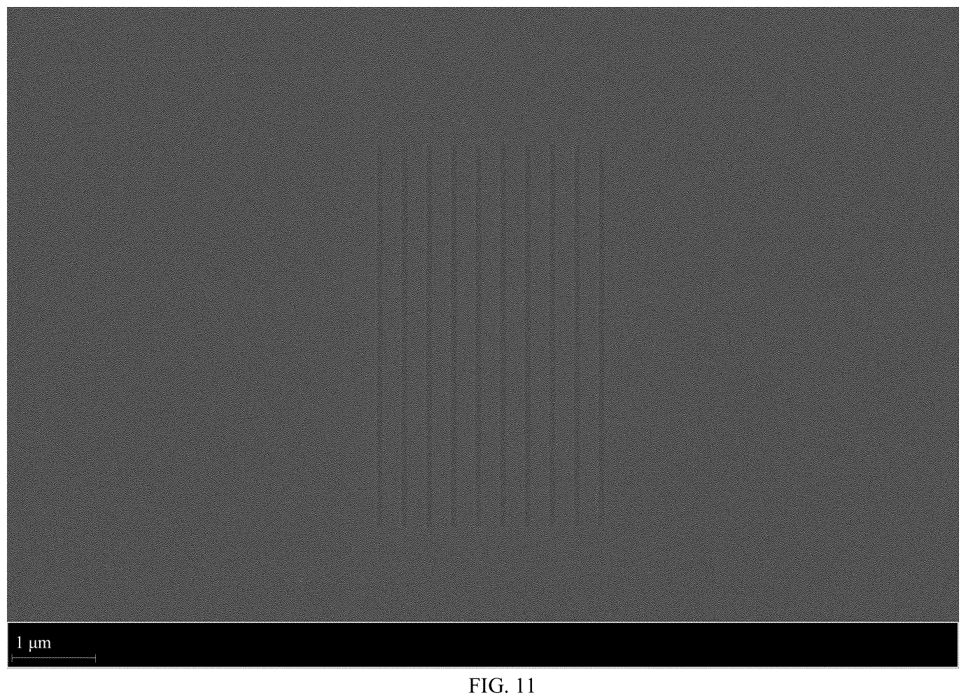

After the patterned substrate is formed using the indium-oxygen cluster compound 2, a width of a line represented and exposed by using the SEM is 100 nm, as shown in FIG. 11.

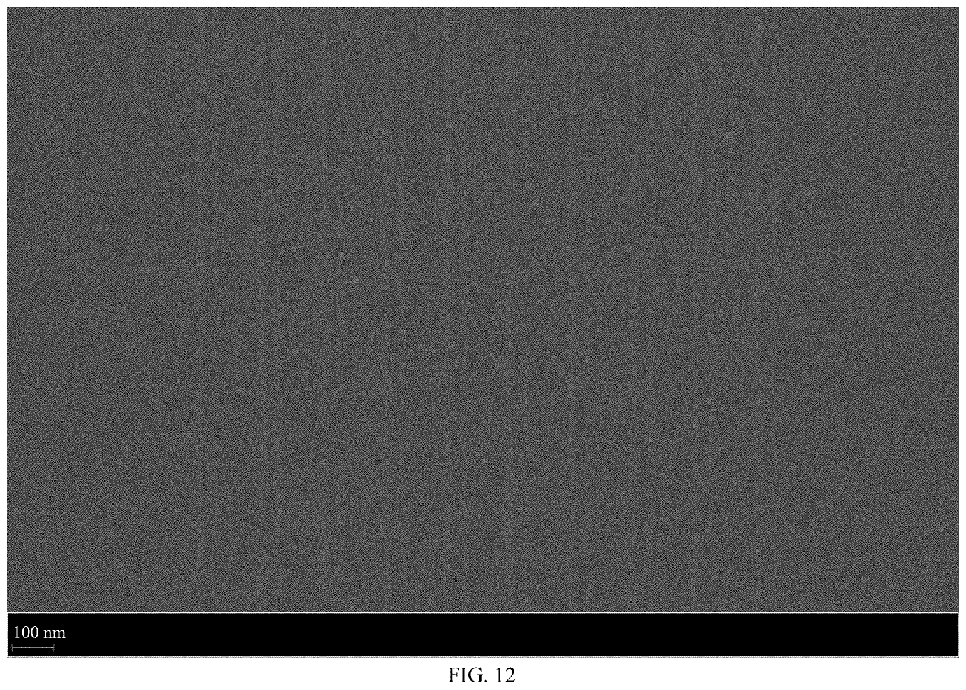

After the patterned substrate is formed using the indium-oxygen cluster compound 2, a width of a line represented and exposed by using the SEM is 50 nm, as shown in FIG. 12.

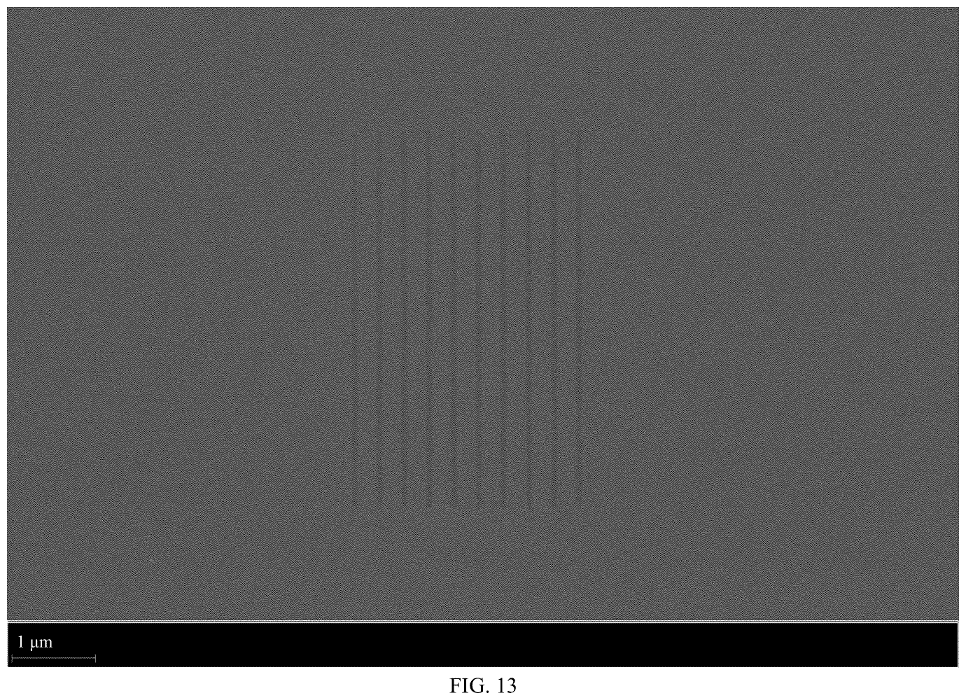

After the patterned substrate is formed using the indium-oxygen cluster compound 9, a width of a line represented and exposed by using the SEM is 100 nm, as shown in FIG. 13.

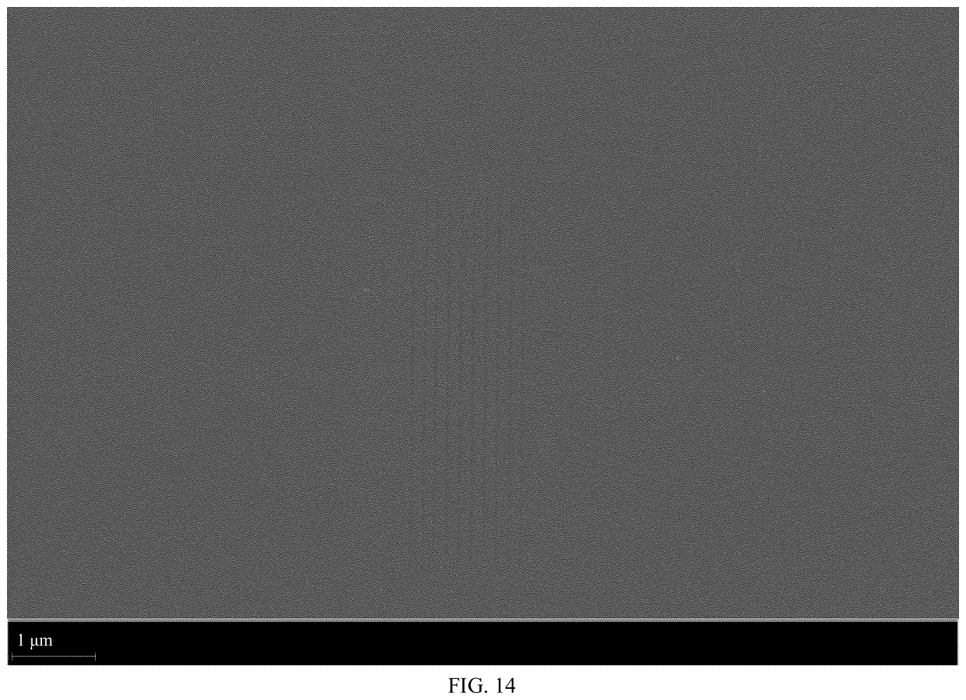

After the patterned substrate is formed using the indium-oxygen cluster compound 9, a width of a line represented and exposed by using the SEM is 50 nm, as shown in FIG. 14.

### Example 2: Based on Radiation-Sensitive Tin-Oxygen Cluster Material

### Example 2-1: Synthesis of Radiation-Sensitive Tin-Oxygen Cluster Material

The following radiation-sensitive tin-oxygen cluster materials were prepared.

Tin-oxygen cluster compound 1: [Sn₁₀O₁₂(L₁)₁₂X₈] (L₁=3-methylpyrazole; X=Cl).

Synthesis method: SnXₙ (1 mmol, X=Cl, n=4) was dissolved in 3 mL of 3-methylpyrazole in a single-mouth glass bottle, heated at 100° C. for three days, and then cooled down to room temperature, to precipitate a colorless crystal.

Tin-oxygen cluster compound 2: [Sn₁₀O₁₂(L₁)₁₂X₈] (L₁=4-methylpyrazole; X=Cl).

Synthesis method: SnXₙ (1 mmol, X=Cl, n=4) was dissolved in 2 mL of 4-methylpyrazole, heated at 100° C. for three days, and then cooled down to room temperature, to precipitate a colorless crystal.

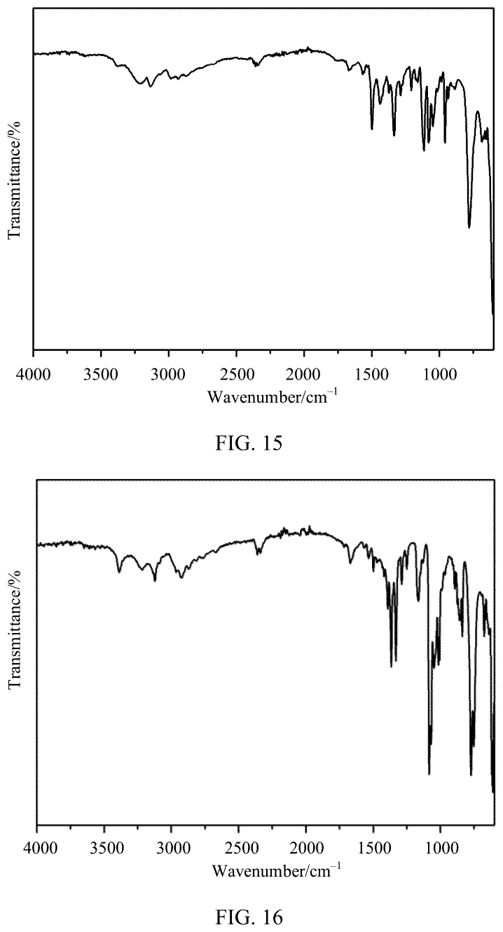

The tin-oxygen cluster compounds 1 and 2 were represented by infrared analysis of solids, to obtain infrared spectra by using Bruker VERTEX 70, as shown in FIG. 15 and FIG. 16.

### Example 2-2: Pattern Forming Method Using Radiation-Sensitive Tin-Oxygen Cluster Material

### (1) Pretreatment of Silicon Wafer

Hydrophilic treatment: A silicon wafer was washed in a Piranha solution (H₂O:30% aqueous ammonia:30% H₂O₂=5:1:1) for 15-20 minutes, then washed with deionized water and then with isopropanol. Before use, the liquid was blown away from the surface of the silicon wafer by using an air syringe.

Hydrophobic treatment: The surface of the silicon wafer obtained through the hydrophilic treatment was covered uniformly by HMDS by vapor deposition or spin coating.

### (2) Coating

8 mg-20 mg of each of the tin-oxygen cluster compounds 1 and 2 was dissolved in ethyl acetate, prior to filtering. A proper amount of filtered solution (negative patterning composition) was spin-coated on the hydrophilic or hydrophobic surface of the silicon wafer to form a tin-oxygen cluster radiation-sensitive coating.

### (3) Exposure

Exposure with radiation: The indium-oxygen cluster patterning material coating was exposed by using an electron-beam etching technology (EBL).

### (4) Developing

A developer includes a mixture of isopropanol and water (in a volume ratio of 10:1 to 1:10) and a mixture of isopropanol (IPA) and PGMEA (in a volume ratio of 10:1 to 1:10). A developing time is 15 s to 60 s.

### (5) Pattern Representation

Each patterned substrate obtained through the developing was represented by using a scanning electron microscope (SEM). The resolution obtained can reach 100 nm or even 50 nm. Details are as follows:

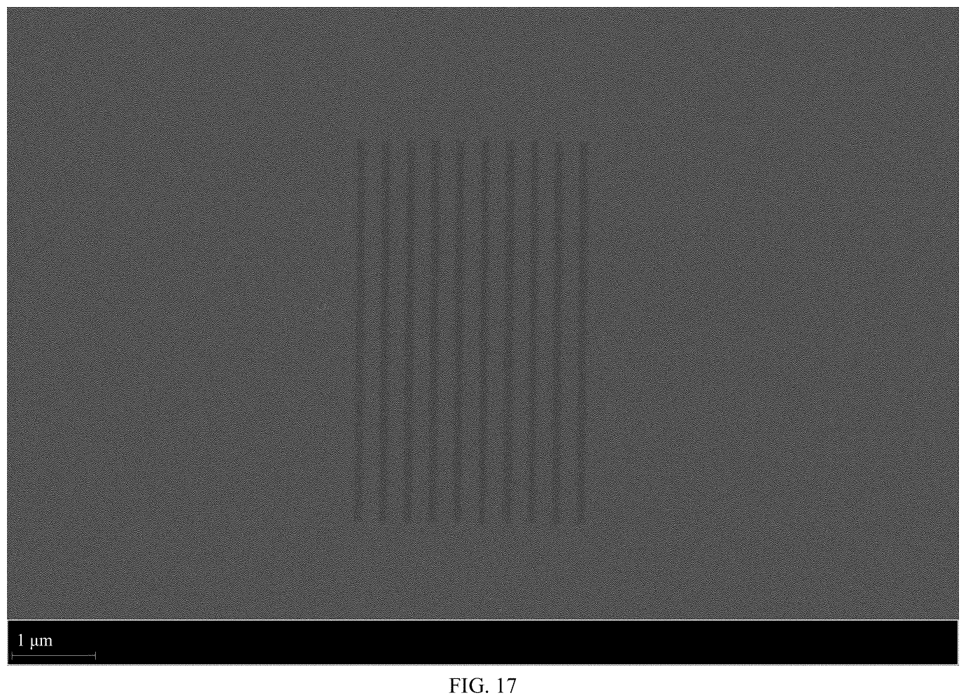

After the patterned substrate is formed using the tin-oxygen cluster compound 2, a width of a line represented and exposed by using the SEM is 100 nm, as shown in FIG. 17.

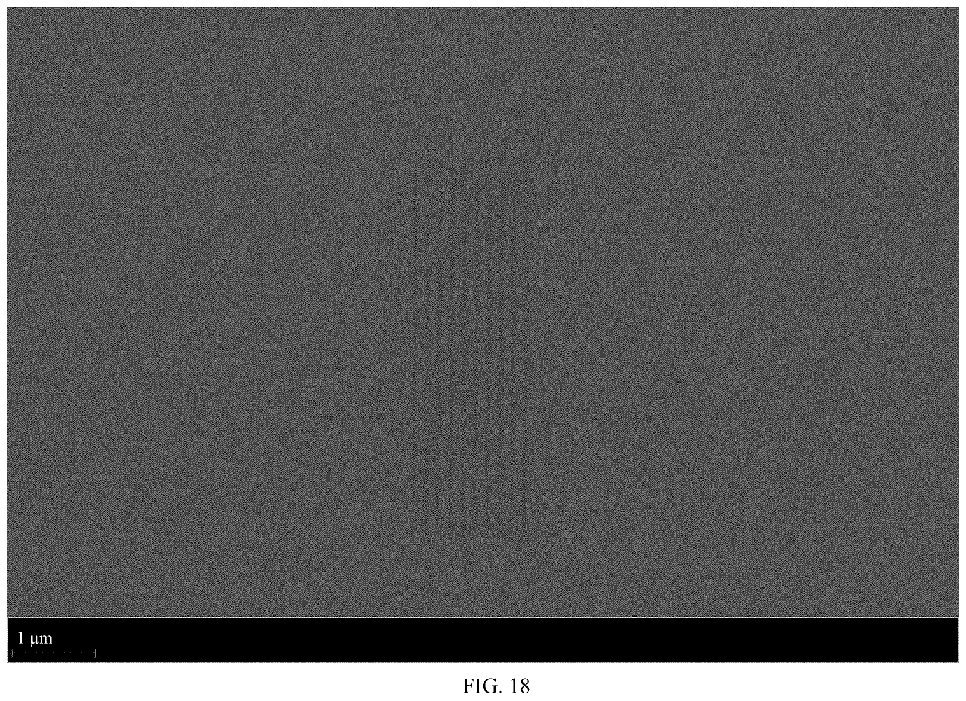

After the patterned substrate is formed using the tin-oxygen cluster compound 2, a width of a line represented and exposed by using the SEM is 50 nm, as shown in FIG. 18.

The flowcharts and the block diagrams in the accompanying drawings illustrate system architectures, functions, and operations of embodiments of apparatuses, systems, methods, and computer program products according to a plurality of embodiments of this application. In this regard, each block in the flowcharts or the block diagrams may represent a module, a program segment, or a part of the instructions, where the module, the program segment, or the part of the instructions includes one or more executable instructions for implementing a specified logical function. In some embodiments, the functions marked in the blocks may also occur in a sequence different from that marked in the accompanying drawings. For example, two consecutive blocks may be executed substantially in parallel, and sometimes may be executed in a reverse order, depending on a function involved.

It should also be noted that each block in the block diagrams and/or the flowcharts and a combination of blocks in the block diagrams and/or the flowcharts may be implemented by hardware (for example, a circuit or an Application Specific Integrated Circuit (ASIC)) that performs a corresponding function or action, or may be implemented by a combination of hardware and software, for example, firmware.

Although the present application is described with reference to embodiments, in a process of implementing the present application that claims protection, a person skilled in the art may understand and implement another variation of the disclosed embodiments by viewing the accompanying drawings, disclosed content, and the accompanying claims. In the claims, “comprising” (comprising) does not exclude another component or another step, and “a” or “one” does not exclude a meaning of plurality. A single processor or another unit may implement several functions enumerated in the claims. Some measures are set forth in dependent claims that are different from each other, but this does not mean that these measures cannot be combined to achieve great effect.

Embodiments of this application are described above. The foregoing descriptions are examples, are not exhaustive, and are not limited to the disclosed embodiments. Many modifications and changes are clear to a person of ordinary skill in the art without departing from the scope and spirit of the described embodiments. The selection of terms used in this specification is intended to best explain the principles of embodiments, practical application, or improvements to technologies in the market, or to enable another person of ordinary skill in the art to understand embodiments disclosed in this specification.

1. A patterning material, comprising:
a metal-oxygen cluster framework formed by a metal M-oxygen bridge bond, a radiation-sensitive organic ligand, and a second ligand;
wherein the radiation-sensitive organic ligand coordinates with the metal M through a coordination atom that is at least one of: an oxygen atom, a sulfur atom, a selenium atom, a nitrogen atom, or a phosphorus atom, the radiation-sensitive organic ligand is a monodentate ligand or a polydentate ligand with a denticity of two or more, and the second ligand is an inorganic ion or a coordination group.

2. The patterning material according to claim 1, wherein the patterning material is represented by the following:
MₓO_{y}(OH)ₙ(L₁)ₐ(L₂)_{b}(L₃)_{c}(L₄)_{d}Xₘ;
wherein
3≤x≤72, 0≤y≤72, 0≤a≤72, 0≤b≤72, 0≤c≤72, 0≤d≤72, 0≤n≤72, 0≤m≤72, y+n+a+b+c+d+m≤8 x, x, y, a, b, c, d, m, and n are integers, and a, b, c, and d are not all 0;
the L₁, L₂, L₃, and L₄ are separately used as the radiation-sensitive organic ligand, or two or more of the L₁, L₂, L₃, and L₄ coexist in a same ligand that is used as the radiation-sensitive organic ligand; and
X is the second ligand.

3. The patterning material according to claim 1, wherein the metal M comprises at least one of: indium, tin, titanium, vanadium, chromium, manganese, iron, cobalt, nickel, copper, zinc, zirconium, niobium, molybdenum, palladium, platinum, silver, cadmium, antimony, tellurium, hafnium, tungsten, gold, lead, or bismuth.

4. The patterning material according to claim 3, wherein the metal M further comprises at least one of: sodium, magnesium, aluminum, potassium, calcium, scandium, gallium, germanium, arsenic, rubidium, strontium, yttrium, technetium, ruthenium, rhodium, cesium, barium, lanthanum, cerium, praseodymium, neodymium, promethium, samarium, europium, gadolinium, terbium, dysprosium, holmium, erbium, thulium, ytterbium, lutecium, tantalum, rhenium, osmium, iridium, mercury, or polonium.

5. The patterning material according to claim 1, wherein the coordination atom is an oxygen atom in the radiation-sensitive organic ligand, the oxygen atom does not form a carboxyl group or a peroxide bond.

6. The patterning material according to claim 1, wherein
the coordination group is at least one of: a halogen group, a carboxylic acid group, a sulfonic acid group, a nitro group, a fatty alcohol group, an aromatic alcohol group, an aliphatic hydrocarbyl group, or an aromatic hydrocarbyl group; and
the inorganic ion is at least one of: a halogen ion, SO₄²⁻, or NO₃⁻.

7. The patterning material according to claim 2, wherein the L₁, L₂, L₃, and L₄ are respectively derived from at least one of: alcohol amine, alcohol, phenol, a nitrogen-containing heterocyclic compound, nitrile, phosphine, phosphonic acid, thiol, or an organic selenium compound.

8. The patterning material according to claim 1, wherein the patterning material is an indium-oxygen cluster material represented by the following:
[M₄(μ4-O)]ₓ₁Mₓ₂O_{y}(OH)ₙXₘ(L₁)ₐ(L₂)_{b}(L₃)_{c}(L₄)_{d};
wherein
M comprises at least indium;
1≤x1≤12, 0≤x2≤24, 0≤y≤24, 0≤a≤36, 0≤b≤36, 0≤c≤36, 0≤d≤36, 0≤n≤24, 0≤m≤24, y+n+m+a+b+c+d≤31(x1)+8(x2), x1, x2, y, a, b, c, d, m, and n are integers, and a, b, c, and d are not all 0;
the L₁, L₂, L₃, and L₄ are separately used as the radiation-sensitive organic ligand, or two or more of the L₁, L₂, L₃, and L₄ coexist in a same ligand that is used as the radiation-sensitive organic ligand; and
X is the second ligand.

9. The patterning material according to claim 8, wherein the radiation-sensitive organic ligand coordinates with the metal M through a nitrogen atom or an oxygen atom as the coordination atom, and the L₁, L₂, L₃, and L₄ are respectively derived from at least one of: alcohol amine, alcohol, phenol, a nitrogen-containing heterocyclic compound, or nitrile.

10. The patterning material according to claim 8, wherein at least one X is a halogen ion or a halogen group.

11. A patterning material, comprising:
a metal-oxygen cluster framework formed by a metal M-oxygen bridge bond, a radiation-sensitive organic ligand, and a second ligand;
wherein
the radiation-sensitive organic ligand coordinates with the metal M through a coordination atom that is at least one of: an oxygen atom, a sulfur atom, a selenium atom, a nitrogen atom, or a phosphorus atom, the radiation-sensitive organic ligand is a monodentate ligand or a polydentate ligand with a denticity of two or more, and the second ligand is an inorganic ion or a coordination group;
the patterning material is a tin-oxygen cluster material represented by the following:
MₓO_{y}(L₁)ₐ(L₂)_{b}Xₘ;
wherein
M comprises at least tin;
3≤x≤34, 0≤y≤51, 0≤a≤51, 0≤b≤51, 0≤m≤51, y+a+b+m≤8 x, x, y, a, b, and m are integers, and a and b are not all 0;
L₁ and L₂ are separately used as the radiation-sensitive organic ligand, or the L₁ and L₂ coexist in a same ligand that is used as the radiation sensitive organic ligand; and
X is the second ligand.

12. The patterning material according to claim 11, wherein the radiation-sensitive organic ligand coordinates with the metal M through a nitrogen atom as the coordination atom, and the L₁ and L₂ are respectively derived from at least one of: alcohol amine, a nitrogen-containing heterocyclic compound, or nitrile.

13. The patterning material according to claim 11, wherein at least one X is a halogen ion or a halogen group.

14. A radiation-sensitive patterning composition, comprising:
a patterning material comprising a metal-oxygen cluster framework formed by a metal M-oxygen bridge bond, a radiation-sensitive organic ligand, and a second ligand;
wherein the radiation-sensitive organic ligand coordinates with the metal M through a coordination atom that is at least one of: an oxygen atom, a sulfur atom, a selenium atom, a nitrogen atom, or a phosphorus atom, the radiation-sensitive organic ligand is a monodentate ligand or a polydentate ligand with a denticity of two or more, and the second ligand is an inorganic ion or a coordination group.

15. The radiation-sensitive patterning composition according to claim 14, further comprising a solvent that is at least one of: carboxylic ester, alcohol with 1 to 8 carbon atoms, aromatic hydrocarbon, halogenated hydrocarbon, or amide.

16. A pattern forming method, comprising:
forming a substrate coated with a radiation-sensitive coating, wherein the radiation-sensitive coating comprises a patterning material;
exposing the substrate with radiation according to a required pattern, to form an exposed structure comprising a region with an exposed coating and a region with an unexposed coating; and
selectively developing the exposed structure to form a patterned substrate with a patterned film;
wherein
the patterning material comprises a metal-oxygen cluster framework formed by a metal M-oxygen bridge bond, a radiation-sensitive organic ligand, and a second ligand;
the radiation-sensitive organic ligand coordinates with the metal M through a coordination atom that is at least one of: an oxygen atom, a sulfur atom, a selenium atom, a nitrogen atom, or a phosphorus atom, the radiation-sensitive organic ligand is a monodentate ligand or a polydentate ligand with a denticity of two or more, and the second ligand is an inorganic ion or a coordination group.

17. A patterned substrate, comprising:
a substrate; and
a patterned film that exists in a selected region on the substrate and does not exist in another region on the substrate;
wherein
the patterned film is formed using a patterning material comprising a metal-oxygen cluster framework formed by a metal M-oxygen bridge bond, a radiation-sensitive organic ligand, and a second ligand;
the radiation-sensitive organic ligand coordinates with the metal M through a coordination atom that is at least one of: an oxygen atom, a sulfur atom, a selenium atom, a nitrogen atom, or a phosphorus atom, the radiation-sensitive organic ligand is a monodentate ligand or a polydentate ligand with a denticity of two or more, and the second ligand is an inorganic ion or a coordination group.

18. The patterned substrate according to claim 17, wherein a pattern resolution of a pattern of the patterned film is between 3 nm nanometer (nm) and 100 nm, and an edge roughness is 2% to 30% of the pattern resolution.

19. A method for patterning a substrate, comprising: performing etching or electron injection on the patterned substrate according to claim 17, to form a patterned structure on a surface of the substrate.

20. An integrated circuit device, comprising: a surface structure formed, by using the method for patterning the substrate according to claim 19, on a silicon wafer as the substrate.
